(19) United States
(12) Patent Application Publication
(10) Pub. No.: US 2026/0006780 A1
(43) Pub. Date: Jan. 1, 2026

(54) SEMICONDUCTOR MEMORY DEVICE

(71) Applicant: Samsung Electronics Co., Ltd., Suwon-si (KR)

(72) Inventors: Jeongsu KIM, Suwon-si (KR); Jinwoo HAN, Suwon-si (KR)

(73) Assignee: Samsung Electronics Co., Ltd., Suwon-si (KR)

(21) Appl. No.: 19/169,064

(22) Filed: Apr. 3, 2025

(30) Foreign Application Priority Data
Jun. 26, 2024 (KR) 10-2024-0083741

(51) Int. Cl. H10B 12/00; H01L 23/00; H01L 25/18; H10D 80/30

(52) U.S. Cl. CPC H10B 12/50; H01L 24/08; H01L 25/18; H10B 12/312; H10D 80/30; H01L 2224/08145; H01L 2924/1436

(57) ABSTRACT

A semiconductor memory device includes a memory cell array structure, the memory cell array structure comprising a cell substrate layer, a cell array element layer on the cell substrate layer, the cell array element layer including a cell transistor and a cell capacitor, and a cell bonding layer on the cell array element layer, a peripheral circuit structure stacked on the memory cell array structure, and the peripheral circuit structure comprising a peripheral epi layer, the peripheral epi layer having an upper surface facing an upward or downward direction, a peripheral circuit element layer on the peripheral epi layer, the peripheral circuit element layer including a peripheral transistor, an etch stopping layer on a lower surface of the peripheral epi layer, and a peripheral bonding layer bonded to the cell bonding layer.

### CROSS-REFERENCE TO RELATED APPLICATIONS

This application is based on and claims priority under 35 U.S.C. § 119 to Korean Patent Application No. 10-2024-0083741, filed on Jun. 26, 2024, in the Korean Intellectual Property Office, the disclosure of which is incorporated by reference herein in its entirety.

### BACKGROUND

Some example embodiments of the inventive concepts relate to a semiconductor memory device, and more particularly, to a semiconductor memory device having a structure including a peripheral circuit structure stacked on a memory cell array structure.

As electronic products become more compact, multifunctional, and highly-performant, the desire for compact, multifunctional, and highly-performant semiconductor memory devices continues to increase. Accordingly, a semiconductor memory device having a structure including a peripheral circuit structure stacked on a memory cell array structure has been proposed.

### SUMMARY

The inventive concepts provide a semiconductor memory device with increased reliability and having a structure including a peripheral circuit structure on a memory cell array structure.

According to some example embodiments of the inventive concepts, there is provided a semiconductor memory device including a memory cell array structure, the memory cell array structure comprising a cell substrate layer, a cell array element layer on the cell substrate layer, the cell array element layer including a cell transistor and a cell capacitor, and a cell bonding layer on the cell array element layer, a peripheral circuit structure stacked on the memory cell array structure, and the peripheral circuit structure comprising a peripheral epi layer, the peripheral epi layer having an upper surface facing an upward or downward direction, a peripheral circuit element layer on the peripheral epi layer, the peripheral circuit element layer including a peripheral transistor, an etch stopping layer on a lower surface of the peripheral epi layer, and a peripheral bonding layer bonded to the cell bonding layer.

According to some example embodiments of the inventive concepts, there is provided a semiconductor memory device including a memory cell array structure, the memory cell array structure comprising a cell substrate layer, a cell array element layer on the cell substrate layer, the cell array element layer including a cell transistor and a cell capacitor, and a cell bonding layer on the cell array element layer, a peripheral circuit structure stacked on the memory cell array structure, the peripheral circuit structure comprising a peripheral epi layer having an upper surface facing an upward direction, a peripheral circuit element layer on the peripheral epi layer, the peripheral circuit element layer including a peripheral transistor, an etch stopping layer on a lower surface of the peripheral epi layer, a peripheral bonding layer on a lower surface of the etch stopping layer, and the peripheral bonding layer bonded to the cell bonding layer; and a connection contact plug vertically connecting the cell array element layer to the peripheral circuit element layer.

According to some example embodiments of the inventive concepts, there is provided a semiconductor memory device including a memory cell array structure, the memory cell array structure comprising a cell substrate, a cell array element layer on the cell substrate, the cell array element layer including a cell transistor and a cell capacitor, a cell bonding layer on the cell array element layer, and a cell bonding pad within the cell bonding layer, a peripheral circuit structure stacked on the memory cell array structure, and the peripheral circuit structure comprising a peripheral epi layer having an upper surface facing a downward direction, a peripheral circuit element layer on the upper surface of the peripheral epi layer, the peripheral circuit element layer including a peripheral transistor, an etch stopping layer on a lower surface of the peripheral epi layer, a peripheral bonding layer on an upper surface of the peripheral circuit element layer, the peripheral bonding layer bonded to the cell bonding layer, a peripheral bonding pad within the peripheral bonding layer, and the peripheral bonding pad bonded to the cell bonding pad.

### BRIEF DESCRIPTION OF THE DRAWINGS

The following example embodiments will be more clearly understood from the following detailed description taken in conjunction with the accompanying drawings in which:

FIG. 1 is a schematic circuit diagram of a semiconductor memory device according to some example embodiments;

FIG. 2 is a schematic circuit diagram of a memory cell array of a semiconductor memory device according to some example embodiments;

FIG. 3 is an exploded perspective view illustrating a portion of a memory cell array of a semiconductor memory device, according to some example embodiments;

FIG. 4 is a schematic cross-sectional view of a semiconductor memory device according to some example embodiments;

FIG. 5 is an enlarged view of a cell array element layer of FIG. 4;

FIG. 6 is a schematic cross-sectional view of a semiconductor memory device according to some example embodiments;

FIG. 7 is a schematic cross-sectional view of a semiconductor memory device according to some example embodiments;

FIG. 8 is an enlarged view of a bonding portion between a memory cell array structure and a peripheral circuit structure of FIG. 7;

FIG. 9 is a schematic cross-sectional view of a semiconductor memory device according to some example embodiments;

FIG. 10 is a schematic circuit diagram of a memory cell array of a semiconductor memory device according to some example embodiments;

FIG. 11 is a schematic cross-sectional view of a semiconductor memory device according to some example embodiments;

FIG. 12 is an enlarged view of the cell array element layer of FIG. 11;

FIG. 13 is an enlarged view of a bonding portion between a memory cell array structure and a peripheral circuit structure of FIG. 11;

FIGS. 14 to 22 are cross-sectional views to describe a method of manufacturing the semiconductor memory device of FIGS. 4 and 5;

FIGS. 23 to 28 are cross-sectional views to describe a method of manufacturing the semiconductor memory device of FIGS. 7 and 8; and

FIGS. 29 to 37 are cross-sectional views to describe a method of manufacturing the semiconductor memory device of FIGS. 11 to 13.

### DETAILED DESCRIPTION

Hereinafter, some example embodiments of the inventive concepts will be described more fully with reference to the accompanying drawings. In the drawings, like elements are labeled like reference numerals and repeated description thereof will be omitted.

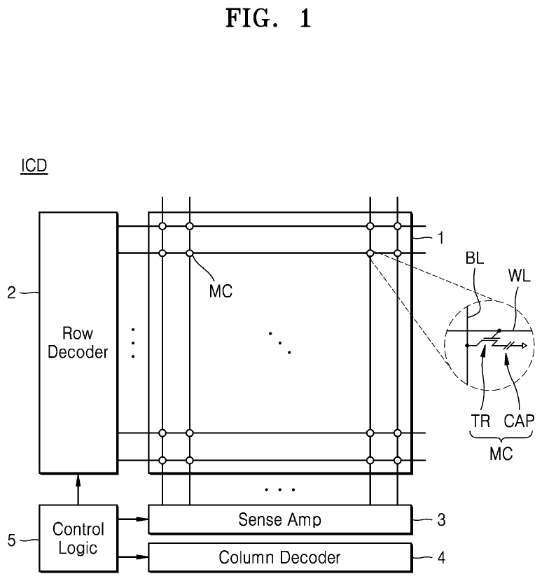

FIG. 1 is a schematic circuit diagram of a semiconductor memory device according to some example embodiments.

A semiconductor memory device ICD shown in FIG. 1 may include a memory cell array 1. The semiconductor memory device ICD may include a dynamic random-access memory (DRAM) device. The memory cell array 1 may include a plurality of memory cells MC arranged three-dimensionally. Each of the memory cells MC may be connected between a word line WL and a bit line BL that intersect each other.

Each memory cell MC may include a cell transistor TR and a cell capacitor CAP. The cell transistor TR and the cell capacitor CAP may be electrically connected to each other in series. The cell transistor TR may be connected between the cell capacitor CAP and the word line WL.

The cell transistor TR may include a field-effect transistor (FET), and the cell capacitor CAP may include a laminated capacitor including a first electrode, a capacitor dielectric layer, and a second electrode. A gate electrode of the cell transistor TR may be connected to the word line WL, and a source and a drain of the cell transistor TR may be connected to the bit line BL and the cell capacitor CAP, respectively.

The semiconductor memory device ICD may include a row decoder 2, a sense amplifier 3, a column decoder 4, and control logic 5. The row decoder 2, the sense amplifier 3, the column decoder 4, and the control logic 5 may be peripheral circuits for transmitting signals and/or power to the memory cell array 1. The row decoder 2, the sense amplifier 3, the column decoder 4, and the control logic 5 may include peripheral transistors for transmitting signals and/or power to the memory cell array 1.

The row decoder 2 may decode an address input from the outside and select one of the word lines WL of the memory cell array 1. An address decoded by the row decoder 2 may be provided to a row driver, and the row driver may provide a certain voltage to each of a selected word line WL and unselected word lines WL in response to the control by the control logic (5, or control logic circuit).

The sense amplifier 3 may detect and amplify a voltage difference between a bit line BL, which is selected according to the address decoded from the column decoder 4, and a reference bit line, and output the voltage difference. The column decoder 4 may provide a data transmission path between the sense amplifier 3 and an external device (e.g., a memory controller).

The column decoder 4 may decode an address input from the outside and select one of the bit lines BL. The control logic 5 may generate control signals that control operations of writing or reading data into or from a memory cell array MCA.

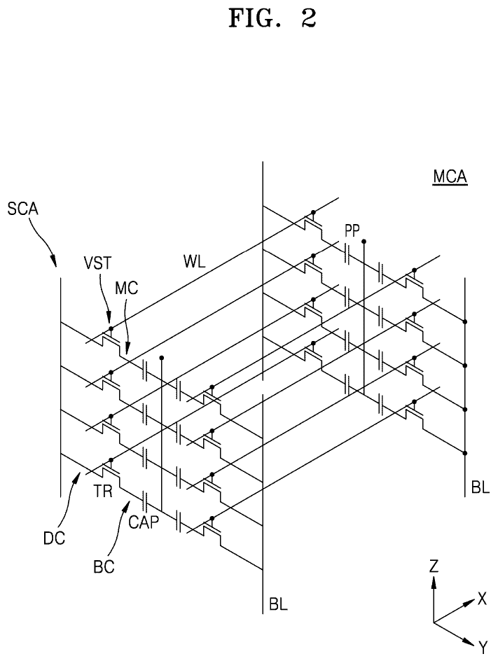

FIG. 2 is a schematic circuit diagram of a memory cell array of a semiconductor memory device according to some example embodiments.

The memory cell array MCA may be a circuit diagram for implementing the memory cell array 1 illustrated in FIG. 1. The memory cell array MCA may include a plurality of sub-cell arrays SCA. The plurality of sub-cell arrays SCA may be arranged apart from each other in a first horizontal direction X.

The sub-cell arrays SCA may include a plurality of bit lines BL, a plurality of word lines WL, and a plurality of memory cells MC. Each of the plurality of memory cells MC may include one cell transistor TR and one cell capacitor CAP connected thereto.

The plurality of word lines WL may extend in the first horizontal direction X and arranged apart from each other in a second horizontal direction Y and a vertical direction Z. The plurality of bit lines BL may extend in the vertical direction Z and arranged apart from each other in the first horizontal direction X and the second horizontal direction Y. One cell transistor TR may be arranged between one word line WL and one bit line BL.

A gate of the cell transistor TR may be connected to the word line WL, and a source of the cell transistor TR may be connected to the bit line BL via a first contact DC. The cell transistor TR may be connected to the cell capacitor CAP through a second contact BC. A drain of the cell transistor TR may be connected to the first electrode of the cell capacitor CAP through the second contact BC, and the second electrode of the cell capacitor CAP may be connected to a plate line PP.

Within one sub-cell array SCA, a plurality of cell transistors TR may be arranged at positions that overlap each other in the vertical direction Z. The cell transistors TR may be three-dimensional vertical stacked transistors VST. Within one sub-cell array SCA, a plurality of cell capacitors CAP may be arranged at positions that overlap each other in the vertical direction Z. One cell transistor TR and one cell capacitor CAP may be arranged side by side at the same vertical level, and a plurality of memory cells MC including one cell transistor TR and one cell capacitor CAP may be stacked in the vertical direction Z.

A storage capacity of the sub-cell array SCA may vary depending on the number or layers of memory cells MC stacked in the vertical direction Z (e.g., the number or layers of the cell capacitors CAP).

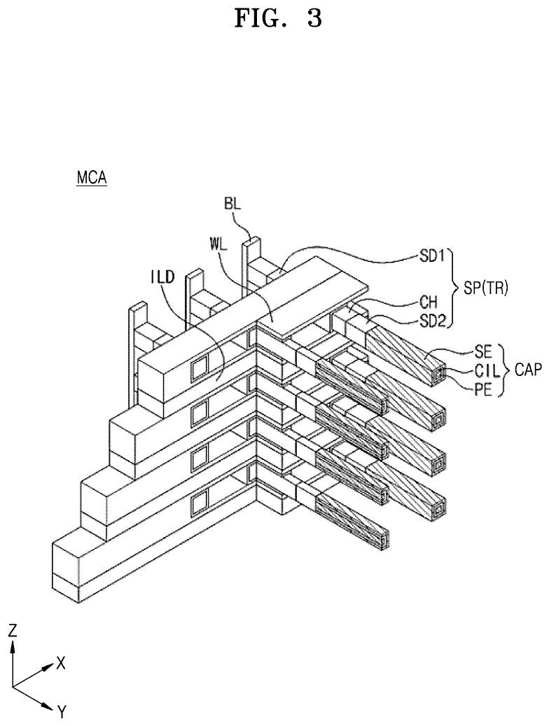

FIG. 3 is an exploded perspective view illustrating a portion of a memory cell array of a semiconductor memory device, according to some example embodiments.

The memory cell array MCA of FIG. 3 may be an exploded perspective view illustrating a portion of the memory cell array 1 illustrated in FIG. 1. The memory cell array MCA may include a plurality of word lines WL stacked on a cell substrate with interlayer insulating patterns ILD therebetween. The word lines WL and the interlayer insulating patterns ILD may be alternately and repeatedly stacked in the vertical direction Z orthogonal to the first horizontal direction X and the second horizontal direction Y.

The memory cell array MCA may include a plurality of semiconductor patterns SP. The semiconductor patterns SP may be stacked in the vertical direction Z and spaced apart from each other in the first horizontal direction X and the second horizontal direction Y. The semiconductor patterns SP may be arranged three-dimensionally on a cell substrate. The semiconductor patterns SP may include at least one of silicon and germanium. For example, the semiconductor patterns SP may include single crystal silicon. However, example embodiments are not limited thereto.

Each of the semiconductor patterns SP may have a bar shape having a relatively long axis in the second horizontal direction Y. Each of the semiconductor patterns SP may include a cell transistor TR. The semiconductor patterns SP may include first and second source/drain regions SD1 and SD2 spaced apart from each other, and a channel region CH between the first and second source/drain regions SD1 and SD2. Impurities may be doped within the first and second source/drain regions SD1 and SD2 of the semiconductor patterns SP.

The semiconductor patterns SP may respectively penetrate the word lines WL in the second horizontal direction Y. The word lines WL may have a structure that completely surrounds the channel region CH of the semiconductor patterns SP (i.e., a gate all around structure). A gate insulating film may be between the channel regions CH of the semiconductor patterns SP and the word lines WL.

The memory cell array MCA may include a plurality of bit lines BL extending in the vertical direction Z across the word lines WL. A first sidewall of the semiconductor patterns SP may be in contact with the bit lines BL, and a second sidewall of the semiconductor patterns SP may be in contact with first electrodes SE. The bit lines BL may have substantially equal lengths in the vertical direction Z.

The bit lines BL may be arranged apart from each other in the first horizontal direction X and the second horizontal direction Y. The bit lines BL may be connected to the first source/drain region SD1 of the semiconductor patterns SP stacked in the vertical direction Z.

The memory cell array MCA may include a plurality of cell capacitors CAP connected to the second source/drain regions SD2 of the semiconductor patterns SP. The first electrodes SE (storage electrodes) of the cell capacitor CAP may be connected to the second source/drain regions SD2 of the semiconductor patterns SP. The first electrodes SE may be provided at substantially the same level as the semiconductor patterns SP.

The first electrodes SE may be stacked in the vertical direction Z and have a relatively long axis in the second horizontal direction Y. The first electrodes SE may be respectively provided between vertically adjacent cell interlayer insulating patterns ILD. The capacitor dielectric layer CIL may conformally cover inner surfaces of the first electrodes SE. Second electrodes PE (i.e., plate electrodes) may fill the interior of the first electrodes SE.

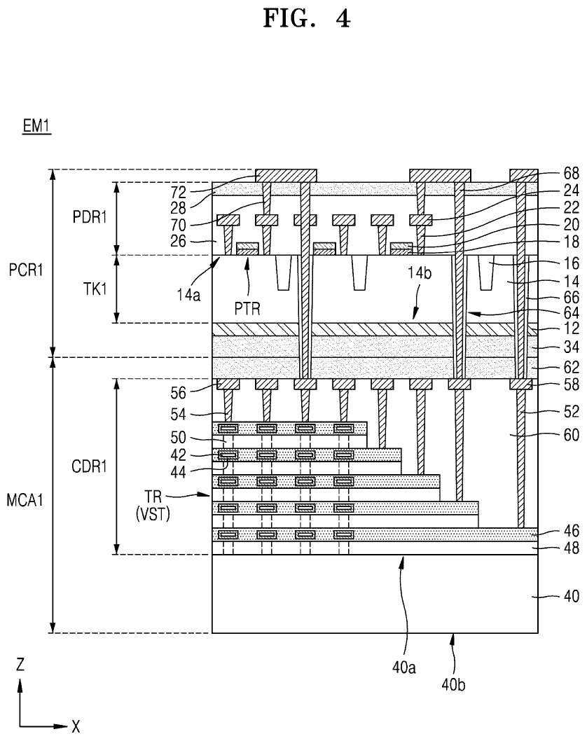

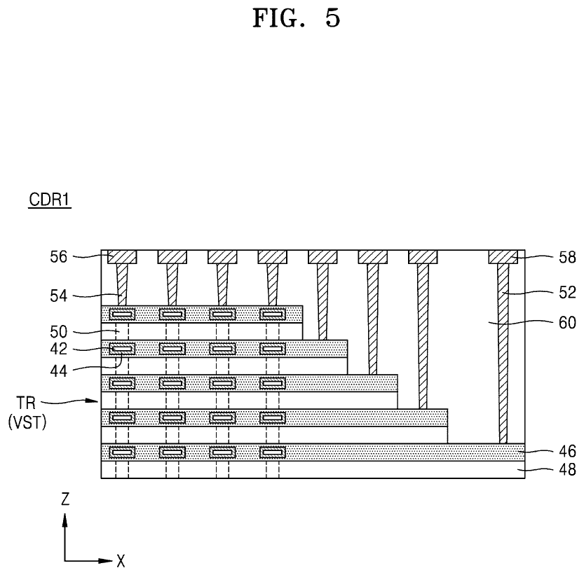

FIG. 4 is a schematic cross-sectional view of a semiconductor memory device according to some example embodiments, and FIG. 5 is an enlarged view of a cell array element layer of FIG. 4.

A semiconductor memory device EM1 may be an example of implementing the semiconductor memory device ICD of FIG. 1. The semiconductor memory device EM1 may include a memory cell array structure MCA1 and a peripheral circuit structure PCR1 stacked on the memory cell array structure MCA1.

The memory cell array structure MCA1 may include the memory cell array MCA of FIGS. 2 and 3. In other words, the memory cell array MCA illustrated in FIGS. 2 and 3 may correspond to the memory cell array structure MCA1. Since the memory cell array structure MCA1 is shown in a cross-sectional view, not all components of the memory cell array MCA of FIGS. 2 and 3 are illustrated in FIG. 4.

The memory cell array structure MCA1 may include a cell substrate layer 40 and a cell array element layer CDR1 disposed on the cell substrate layer 40 and including a cell transistor TR and a cell capacitor CAP (of FIGS. 2 and 3).

The cell substrate layer 40 may be a cell substrate (or cell wafer). The cell substrate layer 40 may be a silicon substrate or a silicon-germanium substrate. However, example embodiments are not limited thereto. The cell substrate layer 40 may include an upper surface 40a and a lower surface 40b. The cell array element layer CDR1 may include word lines 46 extending in the first horizontal direction X and spaced apart from each other by first cell interlayer insulating patterns 48 in the vertical direction (Z direction).

The word lines 46 may have a stairs shape in the first horizontal direction X. The word lines 46 may have a stair shape in which the length thereof in the first horizontal direction X decreases in the vertical direction Z. The word lines 46 may correspond to the word lines WL of FIGS. 2 and 3, and the first cell interlayer insulating patterns 48 may correspond to the cell interlayer insulating patterns ILD of FIG. 3.

The cell array element layer CDR1 may include a cell transistor TR. The cell transistor TR may be a three-dimensional vertical stack transistor VST. The cell transistor TR may include the word lines 46 used as gate electrodes, a channel region 42 penetrating the word lines 46 in the second horizontal direction (Y of FIGS. 2 and 3), and a gate insulating layer 44 surrounding the channel region 42. The word lines 46 may have a structure that completely surrounds the channel region 42 (i.e., a gate all around structure). The channel region 42 may correspond to the channel region CH of FIG. 3.

The cell array element layer CDR1 may include bit lines 50 extending in the vertical direction Z and spaced apart from each other by the first cell interlayer insulating patterns 48 in the first horizontal direction X. The bit lines 50 may correspond to the bit lines BL of FIGS. 2 and 3.

The cell array element layer CDR1 may include a first cell contact plug 52 connected to the word lines 46, and a first cell pad 58 disposed on the first cell contact plug 52. The first cell pad 58 may be a cell pad for word lines.

The cell array element layer CDR1 may include a second cell contact plug 54 connected to bit lines 50, and a second cell pad 56 disposed on the second cell contact plug 54. The second cell pad 56 may be a cell pad for bit lines. The first cell contact plug 52, the second cell contact plug 54, the first cell pad 58, and the second cell pad 56 may be insulated by a second cell interlayer insulating layer 60.

The memory cell array structure MCA1 may include a cell bonding layer 62 disposed on the cell array element layer CDR1. The cell bonding layer 62 may include an insulating layer, such as a silicon oxide layer or a silicon nitride layer. However, example embodiments are not limited thereto.

The peripheral circuit structure PCR1 may include a peripheral epi layer 14 with an upper surface 14a facing an upward direction. The peripheral epi layer 14 may include a silicon layer or a silicon-germanium layer. However, example embodiments are not limited thereto. A device isolation layer 16 may be arranged within the peripheral epi layer 14. An upper width of the device isolation layer 16 may be greater than a lower width thereof.

The peripheral circuit structure PCR1 may include a peripheral circuit element layer PDR1 that is disposed on the peripheral epi layer 14 and includes a peripheral transistor PTR. The peripheral transistor PTR may include a peripheral gate insulating layer, a peripheral gate electrode 18, and a peripheral gate capping layer 20 formed on the upper surface 14a of the peripheral epi layer 14. The peripheral circuit element layer PDR1 may be a peripheral circuit including the row decoder 2, the sense amplifier 3, the column decoder 4, or the control logic 5 described above with reference to FIG. 1.

The peripheral circuit element layer PDR1 may include a first peripheral contact plug 22 connected to the peripheral transistor PTR, and a first peripheral wiring layer 24 connected to the first peripheral contact plug 22. The peripheral circuit element layer PDR1 may include a first peripheral contact plug 22, a first peripheral interlayer insulating layer 26 that insulates the first peripheral contact plug 22, and a peripheral epi bonding insulating layer 28 formed on the first peripheral interlayer insulating layer 26. The peripheral epi bonding insulating layer 28 may include a silicon oxide layer or a silicon nitride layer. The peripheral circuit element layer PDR1 may include a second peripheral contact plug 70 connected to the first peripheral wiring layer 24.

The peripheral circuit structure PCR1 may include an etch stopping layer 12 disposed on a lower surface 14b of the peripheral epi layer 14. The etch stopping layer 12 may act as an etching stopper during manufacturing of a device or may reduce and/or prevent contamination of the peripheral transistor PTR. The etch stopping layer 12 may include a semiconductor epi layer.

The etch stopping layer 12 may include a SiGe layer, a SiGeC layer, or a SiGeB layer. However, example embodiments are not limited thereto. The peripheral epi layer 14 may reduce and/or prevent loss of a thickness TK1 by using the etch stopping layer 12 during a manufacturing process. The peripheral epi layer 14 may also improve thickness uniformity during a manufacturing process by using the etch stopping layer 12.

The peripheral circuit structure PCR1 may include a peripheral bonding layer 34 bonded to the cell bonding layer 62 under the etch stopping layer 12. The peripheral bonding layer 34 may include an insulating layer, such as a silicon oxide layer or a silicon nitride layer. However, example embodiments are not limited thereto.

The peripheral circuit structure PCR1 may include a first connection contact plug 68 that vertically connects the cell array element layer CDR1 to the peripheral circuit element layer PDR1. The first connection contact plug 68 may connect the first peripheral wiring layer 24 to the first and second cell pads 58 and 56 through the second peripheral contact plug 70 and a peripheral pad 72.

The first connection contact plug 68 may be arranged inside the first connection contact hole 64 which is arranged in the peripheral epi layer 14, the etch stopping layer 12, the peripheral bonding layer 34, and the cell bonding layer 62. The first connection contact plug 68 may be insulated from the peripheral epi layer 14 by a liner insulating layer 66 formed on an inner wall of the first connection contact hole 64.

The peripheral circuit structure PCR1 may include the second peripheral contact plug 70 and the peripheral pad 72 disposed on the first connection contact plug 68. The peripheral pad 72 may be connected to the second peripheral contact plug 70 and the first connection contact plug 68.

The semiconductor memory device EM1 as described above includes the etch stopping layer 12 below the peripheral epi layer 14 of the peripheral circuit structure PCR1. Accordingly, in the semiconductor memory device EM1, a decrease in the thickness of the peripheral epi layer 14 may be suppressed or the thickness uniformity of the peripheral epi layer 14 may be improved during a manufacturing process.

In the semiconductor memory device EM1, a depth of the device isolation layer 16 provided on the peripheral epi layer 14 does not need to be deepened by using the etch stopping layer 12 during a manufacturing process. In the semiconductor memory device EM1, the cell bonding layer 62 of the memory cell array structure MCA1 may be easily bonded to the peripheral bonding layer 34 of the peripheral circuit structure PCR1 by improving the thickness uniformity of the peripheral epi layer 14.

During the manufacturing process, in the semiconductor memory device EM1, as the etch stopping layer 12 disposed on the peripheral circuit structure PCR1 acts as a contamination prevention layer, contamination sources may be reduced and/or prevented from flowing into the peripheral circuit structure PCR1. As a result, the semiconductor memory device EM1 may have higher device reliability while having a structure in which the peripheral circuit structure PCR1 is stacked on the memory cell array structure MCA1.

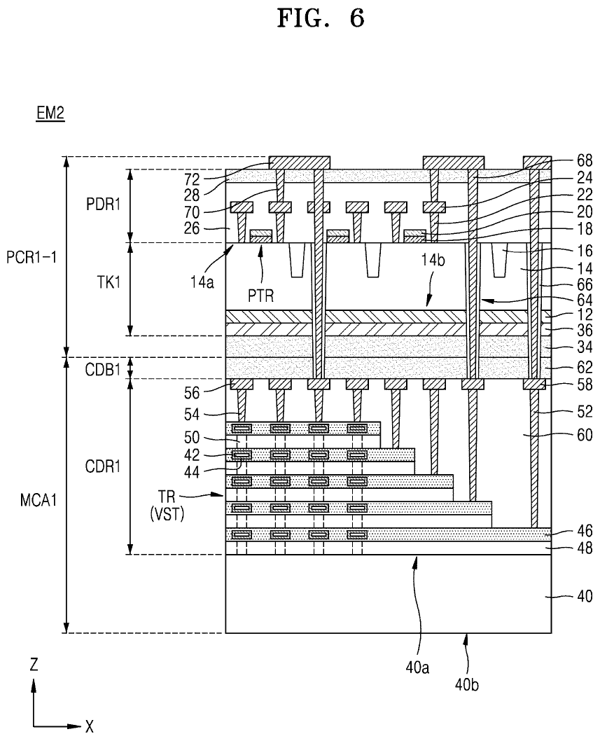

FIG. 6 is a schematic cross-sectional view of a semiconductor memory device according to some example embodiments.

A semiconductor memory device EM2 may be, compared with the semiconductor memory device EM1 of FIGS. 4 and 5, the same except that a peripheral circuit structure PCR1-1 further includes a contaminant penetration prevention layer 36. In FIG. 6, the details described with reference to FIGS. 4 and 5 are briefly described or omitted.

The semiconductor memory device EM2 may include the memory cell array structure MCA1 and the peripheral circuit structure PCR1-1 stacked on the memory cell array structure MCA1. The memory cell array structure MCA1 is as described with reference to FIGS. 4 and 5, and thus the description thereof is omitted here.

The peripheral circuit structure PCR1-1 may include the peripheral epi layer 14 with the upper surface 14a disposed in an upward direction, and the device isolation layer 16 disposed within the peripheral epi layer 14. The peripheral circuit structure PCR1-1 may include the peripheral circuit element layer PDR1 that is disposed on the peripheral epi layer 14 and includes the peripheral transistor PTR.

The peripheral circuit structure PCR1-1 may include the etch stopping layer 12 disposed on the lower surface 14b of the peripheral epi layer 14. The peripheral circuit structure PCR1-1 may include the contaminant penetration prevention layer 36 disposed on a lower surface of the etch stopping layer 12. The contaminant penetration prevention layer 36 may include a metal layer, such as Ti, Ze, Ba, Sr, etc. However, example embodiments are not limited thereto. The peripheral epi layer 14 may further improve device reliability due to the contaminant penetration prevention layer 36 during the manufacturing process.

The peripheral circuit structure PCR1-1 may include a peripheral bonding layer 34 bonded to the cell bonding layer 62 below the contaminant penetration prevention layer 36. The peripheral bonding layer 34 may include an insulating layer, such as a silicon oxide layer or a silicon nitride layer.

The peripheral circuit structure PCR1-1 may include a first connection contact plug 68 that vertically connects the cell array element layer CDR1 to the peripheral circuit element layer PDR1. The first connection contact plug 68 may connect the first peripheral wiring layer 24 to the first and second cell pads 58 and 56 through the second peripheral contact plug 70 and the peripheral pad 72.

As the semiconductor memory device EM2 further includes the contaminant penetration prevention layer 36 disposed on the peripheral circuit structure PCR1-1 during a manufacturing process, contamination sources may be reduced and/or prevented from flowing into the peripheral circuit structure PCR1-1. As a result, the semiconductor memory device EM2 may have higher device reliability while having a structure in which the peripheral circuit structure PCR1-1 is stacked on the memory cell array structure MCA1.

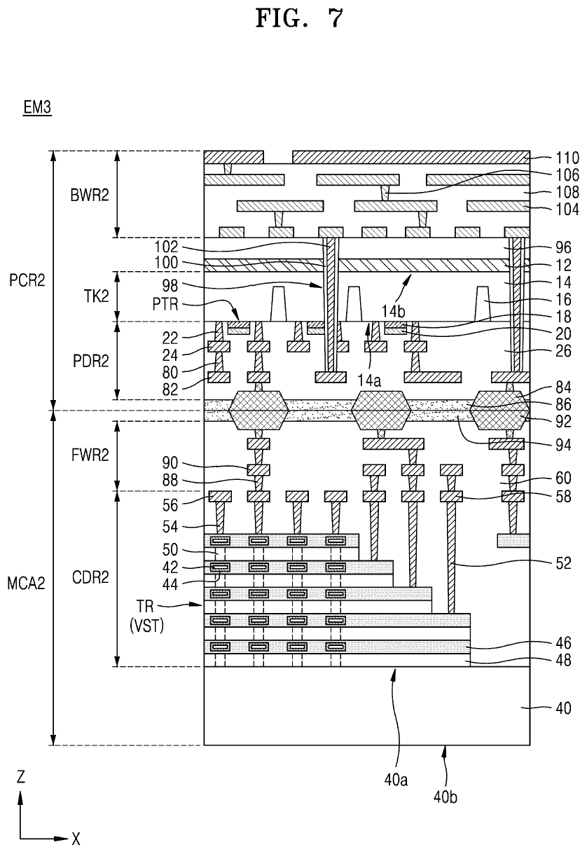

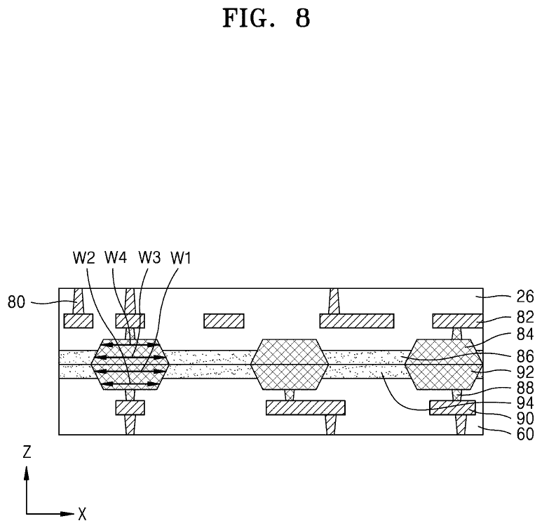

FIG. 7 is a schematic cross-sectional view of a semiconductor memory device according to some example embodiments, and FIG. 8 is an enlarged view of a bonding portion between a memory cell array structure and a peripheral circuit structure of FIG. 7.

A semiconductor memory device EM3 may be the same as the semiconductor memory device EM1 of FIGS. 4 and 5, except that a memory cell array structure MCA2 includes a cell wiring level layer FWR2, a cell bonding pad 92, and a cell bonding layer 94, and a peripheral circuit structure PCR2 includes a peripheral wiring level layer BWR2, a peripheral bonding pad 84, and a peripheral bonding layer 86. In the embodiment of FIGS. 7 and 8, the details described with reference to FIGS. 4 and 5 are briefly described or omitted.

The semiconductor memory device EM3 may include the memory cell array structure MCA2 and the peripheral circuit structure PCR2 stacked on the memory cell array structure MCA2. The memory cell array structure MCA2 may include a cell array element layer CDR2 including a cell substrate layer 40, a cell transistor TR, and a cell capacitor (CAP of FIGS. 2 and 3). The cell array element layer CDR2 is identical to the cell array element layer CDR1 of FIGS. 4 and 5, and thus the description thereof is omitted here.

The memory cell array structure MCA2 may include the cell wiring level layer FWR2 disposed on the cell array element layer CDR2. The cell wiring level layer FWR2 may include a third cell contact plug 88 connected to the first and second cell pads 58 and 56 and a first cell wiring layer 90 connected to the third cell contact plug 88. The cell wiring level layer FWR2 is disposed on the upper surface (40a, or front surface) of the cell substrate layer 40, and thus be referred to as a front cell wiring level layer.

The memory cell array structure MCA2 may include a cell bonding pad 92 and a cell bonding layer 94 disposed on the cell wiring level layer FWR2. The cell bonding pad 92 may be arranged within the cell bonding layer 94.

As illustrated in FIG. 8, both sides of the cell bonding pad 92 may be inclined in a straight line. The cell bonding pad 92 may have an upper width W1 and a lower width W2, and the upper width W1 and the lower width W2 may be different from each other. For example, the upper width W1 may be greater than the lower width W2.

The cell bonding pad 92 may include a metal layer, such as a copper layer. However, example embodiments are not limited thereto. The cell bonding layer 94 may include an insulating layer, such as a silicon oxide layer or a silicon nitride layer.

The peripheral circuit structure PCR2 may include the peripheral epi layer 14 with the upper surface 14a facing a downward direction, and the device isolation layer 16 disposed within the peripheral epi layer 14. The peripheral circuit structure PCR2 may include the peripheral circuit element layer PDR2 that is disposed on the peripheral epi layer 14 and includes the peripheral transistor PTR.

The peripheral circuit element layer PDR2 may include the first peripheral contact plug 22, the first peripheral wiring layer 24, the first peripheral interlayer insulating layer 26, a third peripheral contact plug 80, and a second peripheral wiring layer 82. The first peripheral interlayer insulating layer 26 may insulate between the first peripheral contact plug 22, the first peripheral wiring layer 24, the third peripheral contact plug 80, and the second peripheral wiring layer 82. The first peripheral wiring layer 24 and the second peripheral wiring layer 82 are disposed on the upper surface 14a of the peripheral epi layer 14, and thus may be referred to as upper surface peripheral wiring layers.

The peripheral circuit structure PCR2 may include the etch stopping layer 12 disposed on the lower surface 14b of the peripheral epi layer 14, and a second peripheral interlayer insulating layer 96 disposed on the etch stopping layer 12. The peripheral epi layer 14 may reduce and/or prevent loss of a thickness TK2 by using the etch stopping layer 12 during a manufacturing process. The composition and role of the etch stopping layer 12 have been previously described, and thus a description thereof is omitted here.

The peripheral circuit structure PCR2 includes the peripheral wiring level layer BWR2 disposed on the second peripheral interlayer insulating layer 96. The peripheral wiring level layer BWR2 may include a fourth peripheral contact plug 106, a third peripheral wiring layer 104 connected to the fourth peripheral contact plug 106, and a third peripheral interlayer insulating layer 108 that insulates the fourth peripheral contact plug 106 and the third peripheral wiring layer 104.

The third peripheral wiring layer 104 is arranged above the lower surface (14b, or back surface) of the peripheral epi layer 14, and thus may be referred to as a lower surface peripheral wiring layer. The peripheral wiring level layer BWR2 is arranged above the lower surface (14b, or back surface) of the peripheral epi layer 14, and thus may be referred to as a back surface peripheral wiring level layer. The peripheral wiring level layer BWR2 may include, at an uppermost portion thereof, a peripheral pad 110 connected to a third peripheral wiring layer 104.

The peripheral circuit structure PCR2 may include a second connection contact plug 102 that vertically connects the peripheral circuit element layer PDR2 to the peripheral wiring level layer BWR2. The second connection contact plug 102 may connect the third peripheral wiring layer 104 to the second peripheral wiring layer 82.

The second connection contact plug 102 may be arranged in a second connection contact hole 98 located within the peripheral epi layer 14, the etch stopping layer 12, and the first peripheral interlayer insulating layer 26. The second connection contact plug 102 may be insulated from the peripheral epi layer 14 by a liner insulating layer 100 formed on an inner wall of the second connection contact hole 98.

The peripheral circuit structure PCR2 may include the peripheral bonding pad 84 and the peripheral bonding layer 86 arranged under the peripheral circuit element layer PDR2. The peripheral bonding pad 84 may be arranged within the peripheral bonding layer 86.

As illustrated in FIG. 8, both sides of the peripheral bonding pad 84 may be inclined in a straight line. The peripheral bonding pad 84 may have an upper width W3 and a lower width W4, and the upper width W3 and the lower width W4 may be different from each other. For example, the upper width W3 may be greater than the lower width W4.

The peripheral bonding pad 84 may include a metal layer, for example, a copper layer. However, example embodiments are not limited thereto. The peripheral bonding layer 86 may include an insulating layer, such as a silicon oxide layer or a silicon nitride layer.

The peripheral bonding pad 84 may be bonded to the cell bonding pad 92, and the peripheral bonding layer 86 may be bonded to the cell bonding layer 94. The memory cell array structure MCA2 and the peripheral circuit structure PCR2 may have a hybrid bonding structure that is bonded while including the peripheral bonding pad 84, the peripheral bonding layer 86, the cell bonding pad 92, and the cell bonding layer 94.

As described above, the semiconductor memory device EM3 includes the etch stopping layer 12 disposed on the peripheral circuit structure PCR2 to suppress a decrease in the thickness of the peripheral epi layer 14 and/or to improve the thickness uniformity of the peripheral epi layer 14 during a manufacturing process.

In the semiconductor memory device EM3, the cell bonding layer 94 and the cell bonding pad 92 of the memory cell array structure MCA2 may be easily hybrid-bonded to the peripheral bonding layer 86 and the peripheral bonding pad 84 of the peripheral circuit structure PCR2, respectively, due to the improvement in the thickness uniformity of the peripheral epi layer 14.

In addition, in the semiconductor memory device EM3, as the etch stopping layer 12 disposed on the peripheral circuit structure PCR2 acts as a contamination prevention layer, contamination sources may be reduced and/or prevented from flowing into the peripheral circuit structure PCR2. Accordingly, the semiconductor memory device EM3 may have higher device reliability while having a structure in which the peripheral circuit structure PCR2 is stacked (or bonded) on the memory cell array structure MCA2.

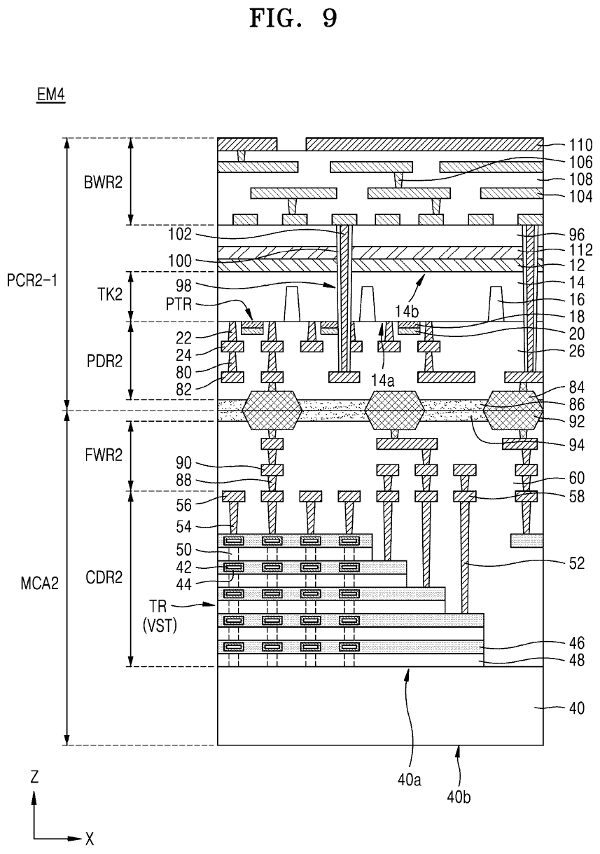

FIG. 9 is a schematic cross-sectional view of a semiconductor memory device according to some example embodiments.

A semiconductor memory device EM4 may be, compared with the semiconductor memory device EM3 of FIGS. 7 and 8, the same except that a peripheral circuit structure PCR2-1 further includes a contaminant penetration prevention layer 112. In the embodiment of FIG. 9, the details described with reference to FIGS. 7 and 8 are briefly described or omitted.

The semiconductor memory device EM4 may include the memory cell array structure MCA2 and the peripheral circuit structure PCR2-1 stacked on the memory cell array structure MCA2. The memory cell array structure MCA2 is as described with reference to FIGS. 7 and 8, and thus the description thereof is omitted here.

The peripheral circuit structure PCR2-1 may include the peripheral epi layer 14 with the upper surface 14a facing a downward direction, and the device isolation layer 16 disposed within the peripheral epi layer 14. The peripheral circuit structure PCR2-1 may include the peripheral circuit element layer PDR2 that is disposed on the peripheral epi layer 14 and includes the peripheral transistor PTR.

The peripheral circuit structure PCR2-1 may include the etch stopping layer 12 disposed on the lower surface 14b of the peripheral epi layer 14. The peripheral circuit structure PCR2-1 may include the contaminant penetration prevention layer 112 disposed on an upper surface of the etch stopping layer 12. The contaminant penetration prevention layer 112 may include a metal layer, such as Ti, Ze, Ba, Sr, etc. However, example embodiments are not limited thereto. The peripheral epi layer 14 may further improve device reliability due to the contaminant penetration prevention layer 112 during a manufacturing process.

The peripheral circuit structure PCR2-1 may include a peripheral bonding pad 84 and a peripheral bonding layer 86 arranged under the peripheral circuit element layer PDR2. The peripheral bonding pad 84 may be bonded to the cell bonding pad 92, and the peripheral bonding layer 86 may be bonded to the cell bonding layer 94.

As the semiconductor memory device EM4 further includes the contaminant penetration prevention layer 112 disposed on the peripheral circuit structure PCR2-1 during a manufacturing process, contamination sources may be reduced and/or prevented from flowing into the peripheral circuit structure PCR2-1. As a result, the semiconductor memory device EM4 may have higher device reliability while having a structure in which the peripheral circuit structure PCR2-1 is stacked on the memory cell array structure MCA2.

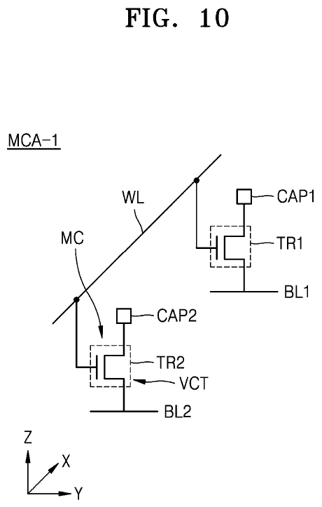

FIG. 10 is a schematic circuit diagram of a memory cell array of a semiconductor memory device according to some example embodiments.

A memory cell array MCA-1 may be a circuit diagram implementing the memory cell array 1 illustrated in FIG. 1. The memory cell array MCA-1 may include a word line WL extending in the first horizontal direction X. The word lines WL may be spaced apart from each other in the second horizontal direction Y.

The memory cell array MCA-1 may include bit lines BL1, BL2 extending in the second horizontal direction Y and spaced apart from each other in the first horizontal direction X. The memory cell array MCA-1 may include a plurality of memory cells MC arranged in the vertical direction Z between the word line WL and the bit lines BL1, BL2. The memory cells MC may include cell transistors TR1, TR2 and cell capacitors CAP1, CAP2. For example, one memory cell MC may include a cell transistor TR1 and a cell capacitor CAP1 connected thereto.

Gates of the cell transistors TR1, TR2 may be connected to the word line WL, and sources of the cell transistors TR1, TR2 may be connected to the bit lines BL1, BL2. Drains of the cell transistors TR1, TR2 may be connected to the cell capacitors CAP1, CAP2.

The cell transistors TR1, TR2 may be arranged in the vertical direction Z between the word line WL and the bit lines BL1, BL2. The cell transistors TR1, TR2 may include vertical channel transistors (VCT).

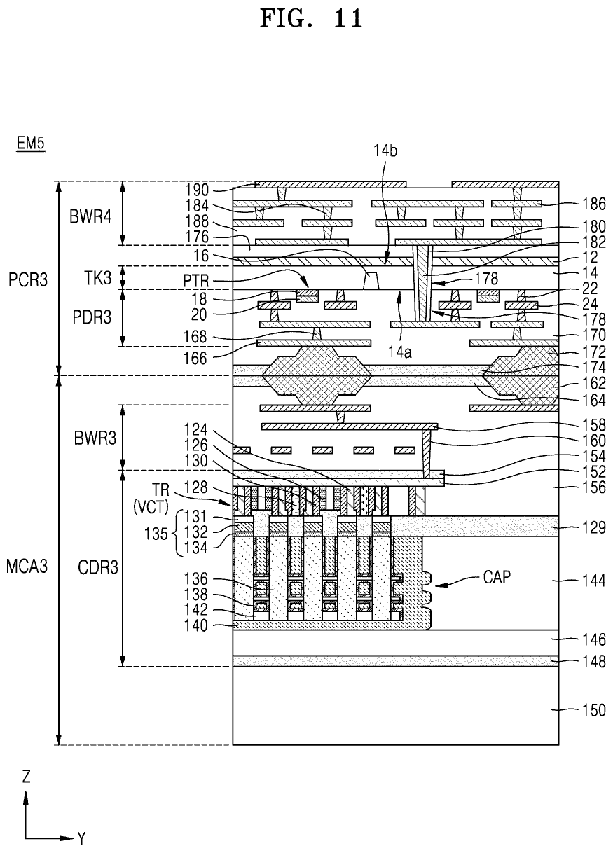

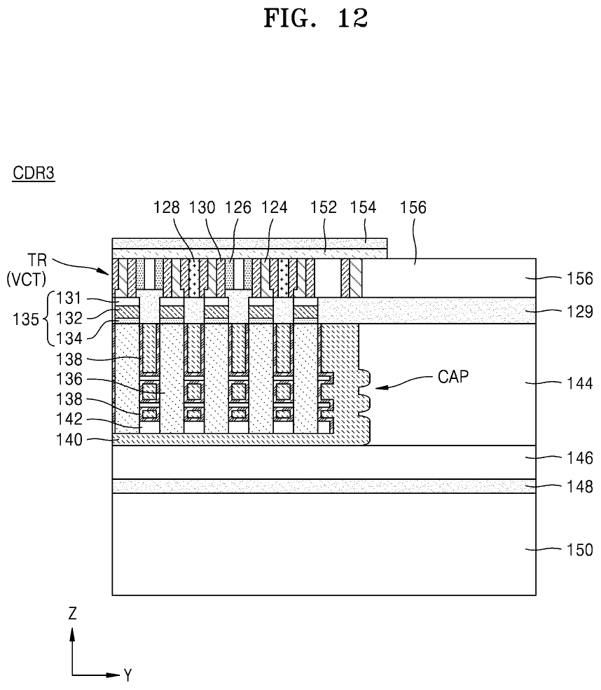

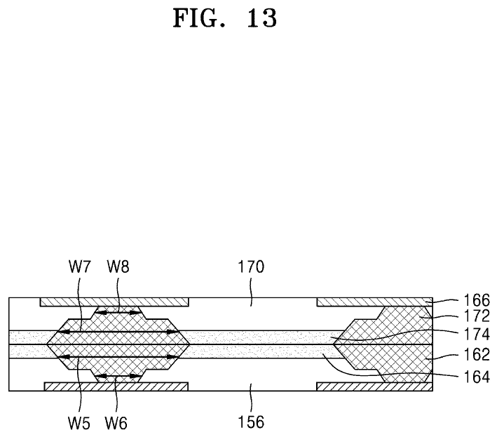

FIG. 11 is a schematic cross-sectional view of a semiconductor memory device according to some example embodiments, FIG. 12 is an enlarged view of a cell array element layer of FIG. 11, and FIG. 13 is an enlarged view of a bonding portion between a memory cell array structure and a peripheral circuit structure of FIG. 11.

A semiconductor memory device EM5 may be an example of implementing the semiconductor memory device ICD of FIG. 1. The semiconductor memory device EM5 may include a memory cell array structure MCA3 and a peripheral circuit structure PCR3 stacked on the memory cell array structure MCA3.

The memory cell array structure MCA3 may include the memory cell array MCA-1 of FIG. 10. In other words, the memory cell array MCA-1 illustrated in FIG. 10 may correspond to the memory cell array structure MCA3. Since the memory cell array structure MCA3 is shown in a cross-sectional view, not all components of the memory cell array MCA-1 of FIG. 10 may be illustrated in FIGS. 11 and 12.

The memory cell array structure MCA3 may include a cell substrate layer 150 and a cell array element layer CDR3 disposed on the cell substrate layer 150 and including a cell capacitor CAP, a cell transistor TR, and a bit line 152. The cell transistor TR may include a vertical channel transistor VCT.

The cell substrate layer 150 may include a cell substrate (or cell wafer). The cell substrate layer 150 may include a silicon substrate or a silicon-germanium substrate. A substrate bonding layer 148 may be further disposed on the cell substrate layer 150. The substrate bonding layer 148 may include a silicon oxide layer or a silicon nitride layer.

The cell array element layer CDR3 may include a capping insulating layer 146 disposed on the substrate bonding layer 148. The capping insulating layer 146 may include a silicon oxide layer. The cell capacitor CAP may be disposed on the capping insulating layer 146.

A capacitor insulating layer 144 that insulates the cell capacitor CAP may be disposed on the capping insulating layer 146. The capacitor insulating layer 144 may include a silicon oxide layer. The cell capacitor CAP may include a laminated capacitor including a first electrode 136, a capacitor dielectric layer 138, and a second electrode 140.

The first electrode 136 may include a plurality of cylindrical electrodes, and supporters 142 may be arranged between the cylindrical electrodes. The capacitor dielectric layer 138 may be disposed on surfaces of the cylindrical electrodes, and the second electrode 140 may be disposed on the capacitor dielectric layer between the cylindrical electrodes.

The cell array element layer CDR3 may include the cell transistor TR connected to the cell capacitor CAP via a contact layer 135. A contact insulating layer 129 that insulates the contact layer 135 may be disposed on the capacitor insulating layer 144.

The contact layer 135 may include a plurality of layers, for example, first to third material layers 131, 132, and 134. The contact layer 135 may include a metal layer. In some example embodiments, the first material layer 131 may include a semiconductor material doped with impurities, such as a silicon layer. However, example embodiments are not limited thereto.

The cell transistor TR may include a semiconductor layer 124 including a channel layer and a source/drain, a gate insulating layer 130, and gate electrodes 126, 128. The gate electrode 128 may be referred to as a back gate electrode.

The semiconductor layer 124 may include a channel layer arranged in the vertical direction (Z direction), and a source and drain arranged above and below the channel layer. The gate electrodes 126, 128 may be connected to the word line WL in the first horizontal direction X as illustrated in FIG. 10.

The cell array element layer CDR3 may include a bit line 152 and a bit line capping layer 154 disposed on the cell transistor TR. The bit line 152 may be one of the bit lines BL1, BL2 of FIG. 10. The source and drain of the cell transistor TR may be connected to the bit line 152 and the cell capacitor CAP, respectively. The bit line 152 may extend in the second horizontal direction Y.

The memory cell array structure MCA3 may include a cell wiring level layer BWR3 disposed on the cell array element layer CDR3. The cell wiring level layer BWR3 may include a fourth cell contact plug 160 connected to the bit line 152 and a second cell wiring layer 158 connected to the fourth cell contact plug 160. The fourth cell contact plug 160 and the second cell wiring layer 158 may be insulated by a third cell interlayer insulating layer 156. The cell wiring level layer BWR3 is arranged after removing a support substrate layer during a manufacturing process and thus may be referred to as a back surface cell wiring level layer.

The memory cell array structure MCA3 may include a cell bonding pad 162 and a cell bonding layer 164 disposed on the cell wiring level layer BWR3. The cell bonding pad 162 may be arranged within the cell bonding layer 164.

As illustrated in FIG. 13, both sides of the cell bonding pad 162 may be inclined in a curved shape. The cell bonding pad 162 may be configured in a stairs shape. The cell bonding pad 162 may have an upper width W5 and a lower width W6, and the upper width W5 and the lower width W6 may be different from each other. For example, the upper width W5 may be greater than the lower width W6.

The cell bonding pad 162 may include a metal layer, such as a copper layer. The cell bonding layer 164 may include an insulating layer, such as a silicon oxide layer or a silicon nitride layer. However, example embodiments are not limited thereto.

The peripheral circuit structure PCR3 may include the peripheral epi layer 14 with the upper surface 14a facing a downward direction, and the device isolation layer 16 disposed within the peripheral epi layer 14. The peripheral circuit structure PCR3 may include a peripheral circuit element layer PDR3 that is disposed on the peripheral epi layer 14 and includes the peripheral transistor PTR.

The peripheral circuit element layer PDR3 may include a first peripheral contact plug 22, a first peripheral wiring layer 24, a fourth peripheral interlayer insulating layer 170, a fifth peripheral contact plug 168, and a fourth peripheral wiring layer 166. The fourth peripheral interlayer insulating layer 170 may insulate between the first peripheral contact plug 22, the first peripheral wiring layer 24, the fifth peripheral contact plug 168, and the fourth peripheral wiring layer 166. The first peripheral wiring layer 24 and the fourth peripheral wiring layer 166 are disposed on the upper surface 14a of the peripheral epi layer 14, and thus may be referred to as upper surface peripheral wiring layers.

The peripheral circuit structure PCR3 may include the etch stopping layer 12 disposed on the lower surface 14b of the peripheral epi layer 14, and a fifth peripheral interlayer insulating layer 176 disposed on the etch stopping layer 12. The peripheral epi layer 14 may reduce and/or prevent loss of a thickness TK3 by using the etch stopping layer 12 during a manufacturing process. The composition and role of the etch stopping layer 12 have been described above, and thus a description thereof is omitted here.

The peripheral circuit structure PCR3 includes a peripheral wiring level layer BWR4 disposed on the fifth peripheral interlayer insulating layer 176. The peripheral wiring level layer BWR4 may include a sixth peripheral contact plug 184, a fifth peripheral wiring layer 186 connected to the sixth peripheral contact plug 184, and a sixth peripheral interlayer insulating layer 188 that insulates the sixth peripheral contact plug 184 and the fifth peripheral wiring layer 186.

The fifth peripheral wiring layer 186 is arranged above the lower surface (14b, or back surface) of the peripheral epi layer 14, and thus may be referred to as a lower surface peripheral wiring layer. The peripheral wiring level layer BWR4 is arranged above the lower surface (14b, or back surface) of the peripheral epi layer 14, and thus may be referred to as a back surface peripheral wiring level layer. The peripheral wiring level layer BWR4 may include, at an uppermost portion, a peripheral pad 190 connected to the fifth peripheral wiring layer 186.

The peripheral circuit structure PCR3 may include a third connection contact plug 182 that vertically connects the peripheral circuit element layer PDR3 to the peripheral wiring level layer BWR4. The third connection contact plug 182 may connect the fourth peripheral wiring layer 166 to the fifth peripheral wiring layer 186.

The third connection contact plug 182 may be arranged in a third connection contact hole 178 located within the peripheral epi layer 14, the etch stopping layer 12, and the fifth peripheral interlayer insulating layer 176. The third connection contact plug 182 may be insulated from the peripheral epi layer 14 by a liner insulating layer 180 formed on an inner wall of the third connection contact hole 178.

The peripheral circuit structure PCR3 may include a peripheral bonding pad 172 and a peripheral bonding layer 174 arranged under the peripheral circuit element layer PDR3. The peripheral bonding pad 172 may be arranged within the peripheral bonding layer 174.

As illustrated in FIG. 13, both sides of the peripheral bonding pad 172 may be inclined in a curved shape. The peripheral bonding pads 172 may be configured in a stairs shape. The peripheral bonding pad 172 may have an upper width W7 and a lower width W8, and the upper width W7 and the lower width W8 may be different from each other. For example, the upper width W7 may be greater than the lower width W8.

The peripheral bonding pad 172 may include a metal layer, for example, a copper layer. However, example embodiments are not limited thereto. The peripheral bonding layer 174 may include an insulating layer, such as a silicon oxide layer or a silicon nitride layer. However, example embodiments are not limited thereto.

The peripheral bonding pad 172 may be bonded to the cell bonding pad 162, and the peripheral bonding layer 174 may be bonded to the cell bonding layer 164. The memory cell array structure MCA3 and the peripheral circuit structure PCR3 may have a hybrid bonding structure that is bonded while including the peripheral bonding pad 172, the peripheral bonding layer 174, the cell bonding pad 162, and the cell bonding layer 164.

As described above, as the semiconductor memory device EM4 includes the etch stopping layer 12 disposed on the peripheral circuit structure PCR3, a decrease in the thickness of the peripheral epi layer 14 may be suppressed and/or the thickness uniformity of the peripheral epi layer 14 may be improved during the manufacturing process.

In the semiconductor memory device EM4, the cell bonding layer 164 and the cell bonding pad 162 of the memory cell array structure MCA3 may be easily hybrid-bonded to the peripheral bonding layer 174 and the peripheral bonding pad 172 of the peripheral circuit structure PCR3, respectively, due to the improvement in the thickness uniformity of the peripheral epi layer 14.

In addition, in the semiconductor memory device EM4, as the etch stopping layer 12 disposed on the peripheral circuit structure PCR3 acts as a contamination prevention layer, contamination sources may be reduced and/or prevented from flowing into the peripheral circuit structure PCR3. Accordingly, the semiconductor memory device EM4 may have higher device reliability while having a structure in which the peripheral circuit structure PCR3 is stacked (or bonded) on the memory cell array structure MCA3.

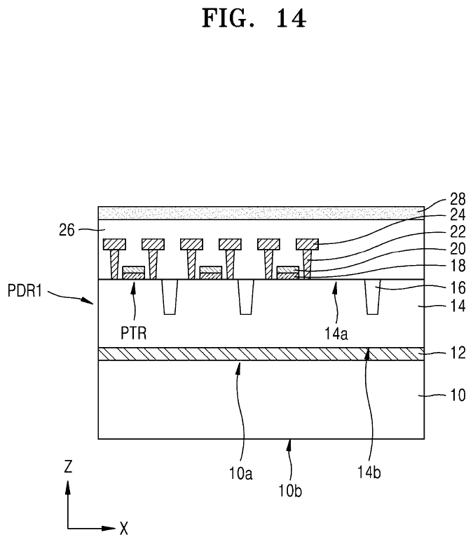

FIGS. 14 to 22 are cross-sectional views to describe a method of manufacturing the semiconductor memory device EM1 of FIGS. 4 and 5.

In FIGS. 14 to 22, the same reference numerals as those in FIGS. 4 and 5 denote the same elements. In FIGS. 14 to 22, the details described with reference to FIGS. 4 and 5 are briefly described or omitted.

Referring to FIG. 14, a peripheral circuit element layer PDR1 constituting a peripheral circuit structure (PCR1 of FIG. 4) is formed on a first support substrate layer 10. The first support substrate layer 10 may include a silicon substrate. The first support substrate layer 10 may include an upper surface 10a and a lower surface 10b. The peripheral circuit element layer PDR1 may be formed on the upper surface 10a of the first support substrate layer 10.

The peripheral circuit element layer PDR1 may include the etch stopping layer 12, the peripheral epi layer 14, the peripheral transistor PTR, the first peripheral contact plug 22, the first peripheral wiring layer 24, and the peripheral epi bonding insulating layer 28.

The etch stopping layer 12 is formed by depositing a semiconductor epi layer on the first support substrate layer 10. The etch stopping layer 12 may include a SiGe layer, a SiGeC layer, or a SiGeB layer. The peripheral epi layer 14 is formed on the etch stopping layer 12. The peripheral epi layer 14 may include the upper surface 14a and the lower surface 14b. The peripheral epi layer 14 includes a silicon layer or a silicon-germanium layer. However, example embodiments are not limited thereto.

The peripheral transistor PTR is formed on the upper surface 14a of the peripheral epi layer 14. The peripheral transistor PTR may include a peripheral gate insulating layer, a peripheral gate electrode 18, and a peripheral gate capping layer 20 formed on the upper surface 14a of the peripheral epi layer 14.

The first peripheral contact plug 22 and the first peripheral wiring layer 24 connected to the peripheral transistor PTR are formed on the peripheral transistor PTR. The first peripheral contact plug 22 and the first peripheral wiring layer 24 are insulated by the first peripheral interlayer insulating layer 26. The peripheral epi bonding insulating layer 28 is formed on the first peripheral interlayer insulating layer 26. The peripheral epi bonding insulating layer 28 may include a silicon oxide layer or a silicon nitride layer. However, example embodiments are not limited thereto.

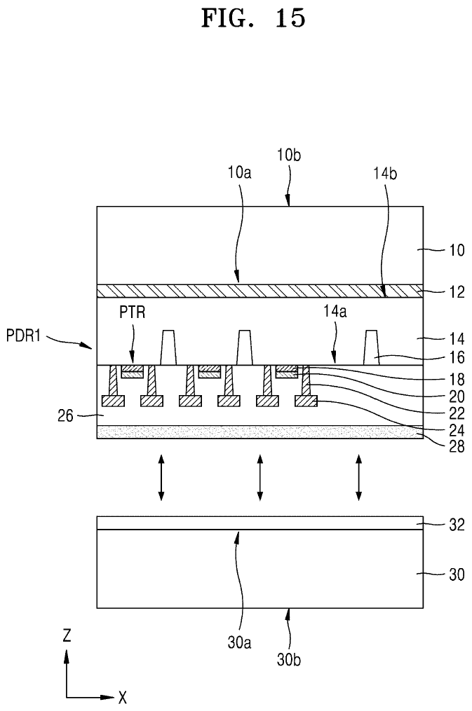

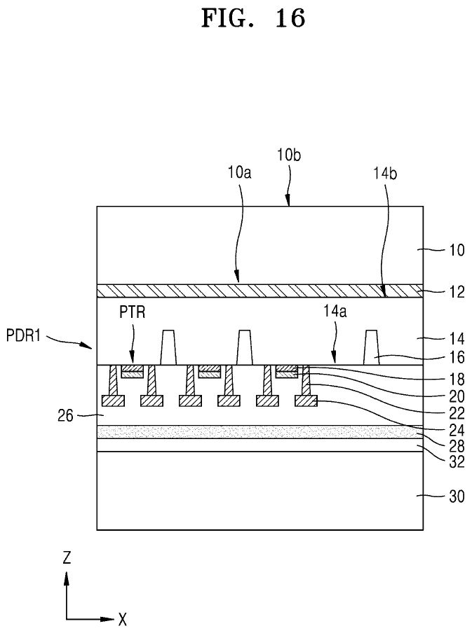

Referring to FIGS. 15 and 16, a second support substrate layer 30 is prepared as illustrated in FIG. 15. The second support substrate layer 30 may include a silicon substrate. The second support substrate layer 30 may include an upper surface 30a and a lower surface 30b. A support bonding insulating layer 32 is formed on the upper surface 30a of the second support substrate layer 30. The support bonding insulating layer 32 includes a silicon oxide layer or a silicon nitride layer. However, example embodiments are not limited thereto.

Further, as illustrated in FIG. 15, the first support substrate layer 10 and the peripheral circuit element layer PDR1, which are a resultant product of the embodiment of FIG. 14 are turned over. Then the peripheral circuit element layer PDR1 is located at the bottom. The upper surface 14a of the peripheral epi layer 14 is located at the bottom, and the peripheral epi bonding insulating layer 28 is located at the lowest part.

As illustrated in FIG. 15, the peripheral circuit element layer PDR1 including the peripheral epi bonding insulating layer 28 and the first support substrate layer 10 are positioned on the second support substrate layer 30 on which the support bonding insulating layer 32 is formed. Next, as illustrated in FIG. 16, the peripheral epi bonding insulating layer 28 and the support bonding insulating layer 32 are bonded to each other through a heat treatment process (or annealing process).

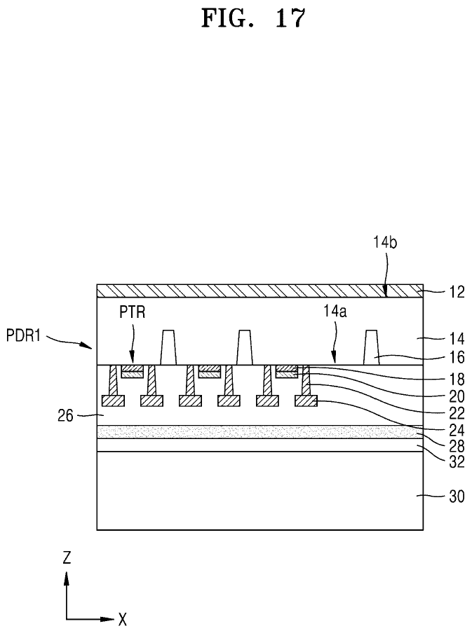

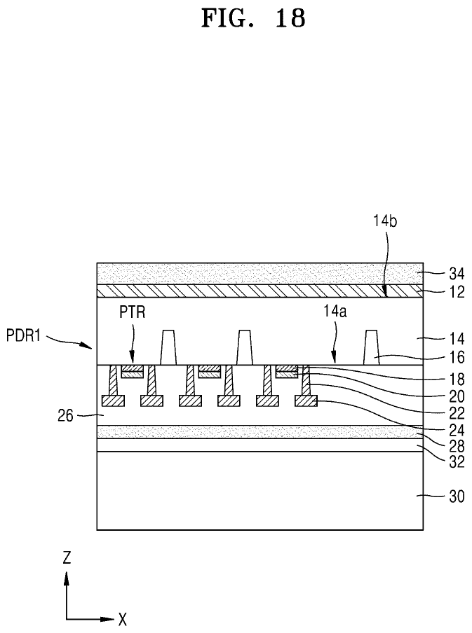

Referring to FIGS. 17 and 18, the first support substrate layer (10 of FIG. 16) is removed through a chemical mechanical polishing process as illustrated in FIG. 17. During the chemical mechanical polishing process, the etch stopping layer 12 acts as an etch stopping point, thereby suppressing thickness loss of the peripheral epi layer 14. The peripheral epi layer 14 may also improve thickness uniformity by suppressing thickness loss during the manufacturing process by using the etch stopping layer 12.

As illustrated in FIG. 18, a peripheral bonding layer 34 is formed on the etch stopping layer 12. The peripheral bonding layer 34 includes an insulating layer, such as a silicon oxide layer or a silicon nitride layer. However, example embodiments are not limited thereto.

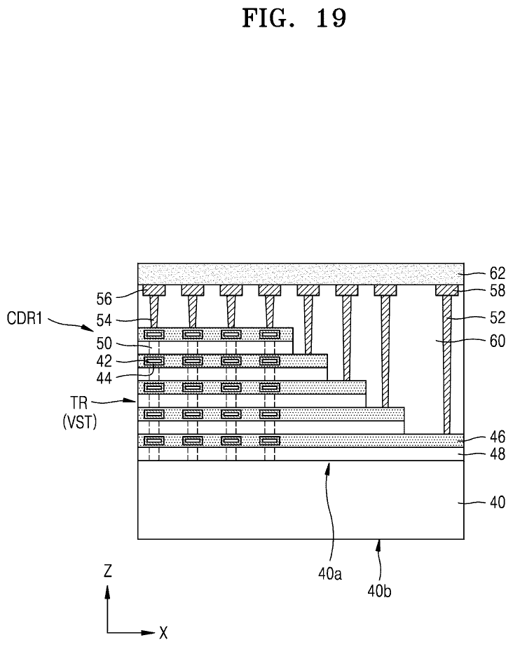

Referring to FIG. 19, the cell array element layer CDR1 and the cell bonding layer 62 are formed on a cell substrate layer 40. The cell substrate layer 40, the cell array element layer CDR1, and the cell bonding layer 62 constitute a memory cell array structure (MCA1 in FIG. 4).

The cell substrate layer 40 may include a silicon substrate or a silicon-germanium substrate. The cell substrate layer 40 may include an upper surface 40a and a lower surface 40b. The cell array element layer CDR1 may include the cell transistor TR and the cell capacitor (CAP of FIGS. 2 and 3). The cell transistor TR may be a three-dimensional vertical stack transistor VST.

The cell array element layer CDR1 may include a channel region 42, a gate insulating layer 44, word lines 46, first cell interlayer insulating patterns 48, and bit lines 50. The cell array element layer CDR1 may include a first cell contact plug 52, a first cell pad 58, a second cell contact plug 54, a second cell pad 56, and a second cell interlayer insulating layer 60. The cell bonding layer 62 is formed on the cell array element layer CDR1. The cell bonding layer 62 includes an insulating layer, such as a silicon oxide layer or a silicon nitride layer. However, example embodiments are not limited thereto.

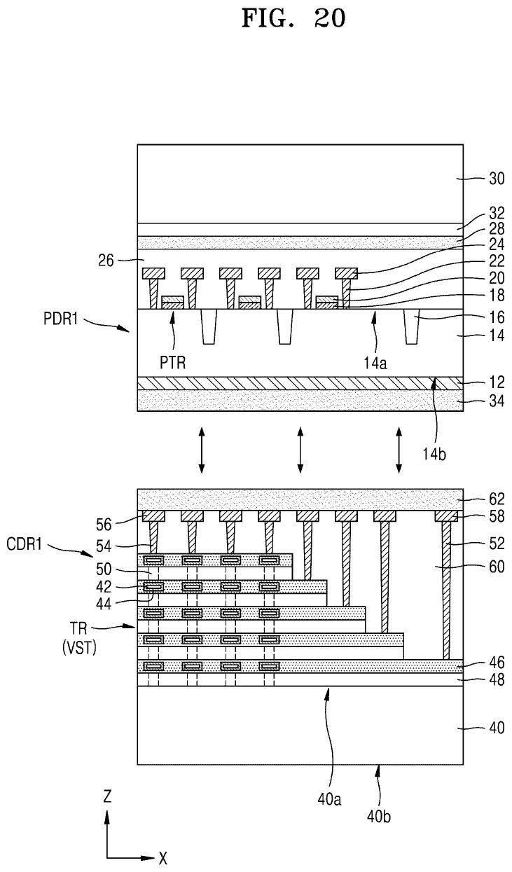

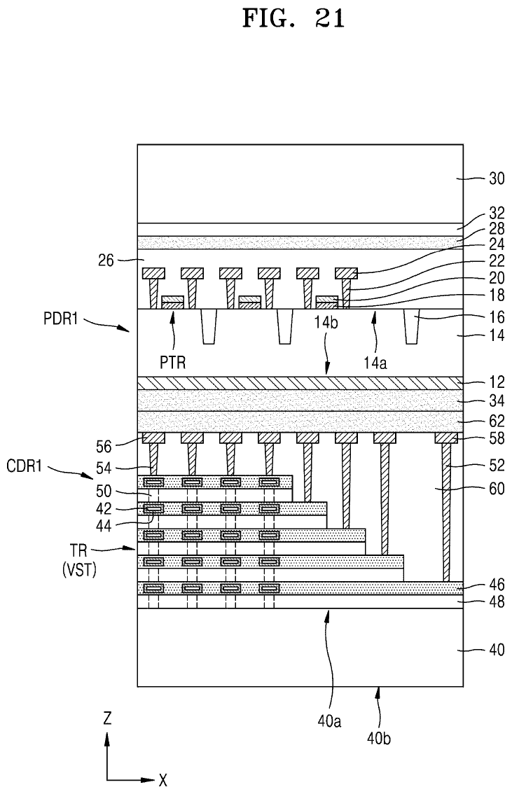

Referring to FIGS. 20 and 21, a resultant product of FIG. 18 is turned over as illustrated in FIG. 20. Then the peripheral circuit element layer PDR1 is located at the top. The lower surface 14b of the peripheral epi layer 14 is located at the bottom, and the peripheral bonding layer 34 is located at the lowest part.

The peripheral circuit element layer PDR1 including the lower surface 14b of the peripheral epi layer 14 in a lower portion thereof and the peripheral bonding layer 34 in a lowermost portion thereof is positioned above the cell array element layer CDR1 and the cell bonding layer 62 formed on the cell substrate layer 40. Next, as illustrated in FIG. 21, the peripheral bonding layer 34 and the cell bonding layer 62 are bonded to each other through a heat treatment process (or annealing process).

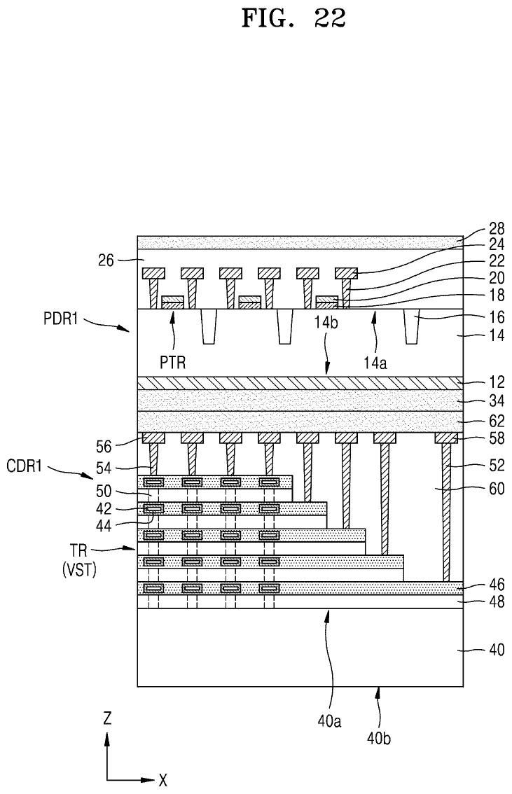

Referring to FIG. 22, the second support substrate layer (30 of FIG. 21) and the support bonding insulating layer (32 of FIG. 21) are removed through a chemical mechanical polishing process. During the chemical mechanical polishing process, the peripheral epi bonding insulating layer 28 may act as an etch stopping point.

Further, as illustrated in FIG. 4, the first connection contact plug 68, the second peripheral contact plug 70, and the peripheral pad 72 are formed to complete the semiconductor memory device EM1.

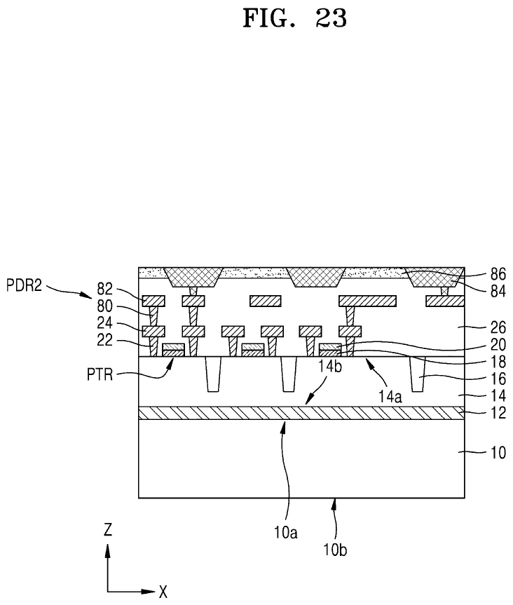

FIGS. 23 to 28 are cross-sectional views to describe a method of manufacturing the semiconductor memory device EM3 of FIGS. 7 and 8.

In FIGS. 23 to 28, the same reference numerals as those in FIGS. 7 and 8 denote the same elements. In FIGS. 14 to 22, the details described with reference to FIGS. 7 and 8 are briefly described or omitted.

Referring to FIG. 23, the peripheral circuit element layer PDR2 constituting a peripheral circuit structure (PCR2 of FIG. 7) is formed on the first support substrate layer 10. The first support substrate layer 10 may include a silicon substrate. The first support substrate layer 10 may include an upper surface 10a and a lower surface 10b. The peripheral circuit element layer PDR2 may be formed on the upper surface 10a of the first support substrate layer 10.

The peripheral circuit element layer PDR2 may include the etch stopping layer 12, the peripheral epi layer 14, the peripheral transistor PTR, the first peripheral contact plug 22, the first peripheral wiring layer 24, the first peripheral interlayer insulating layer 26, the third peripheral contact plug 80, and the second peripheral wiring layer 82.

The etch stopping layer 12 is formed by depositing a semiconductor epi layer on the first support substrate layer 10. The etch stopping layer 12 may include a SiGe layer, a SiGeC layer, or a SiGeB layer. However, example embodiments are not limited thereto. The peripheral epi layer 14 is formed on the etch stopping layer 12. The peripheral epi layer 14 may include the upper surface 14a and the lower surface 14b. The peripheral epi layer 14 includes a silicon layer or a silicon-germanium layer. However, example embodiments are not limited thereto.

The peripheral transistor PTR is formed on the upper surface 14a of the peripheral epi layer 14. The peripheral transistor PTR may include the peripheral gate insulating layer, the peripheral gate electrode 18, and the peripheral gate capping layer 20 formed on the upper surface 14a of the peripheral epi layer 14.

The first peripheral contact plug 22, the first peripheral wiring layer 24, the third peripheral contact plug 80, and the second peripheral wiring layer 82 connected to the peripheral transistor PTR are formed on the peripheral transistor PTR. The first peripheral contact plug 22, the first peripheral wiring layer 24, the third peripheral contact plug 80, and the second peripheral wiring layer 82 are insulated by the first peripheral interlayer insulating layer 26.

The peripheral bonding pad 84 and the peripheral bonding layer 86 are formed on the first peripheral interlayer insulating layer 26. The peripheral bonding pad 84 includes a metal layer, for example, a copper layer. The peripheral bonding layer 86 includes an insulating layer, such as a silicon oxide layer or a silicon nitride layer.

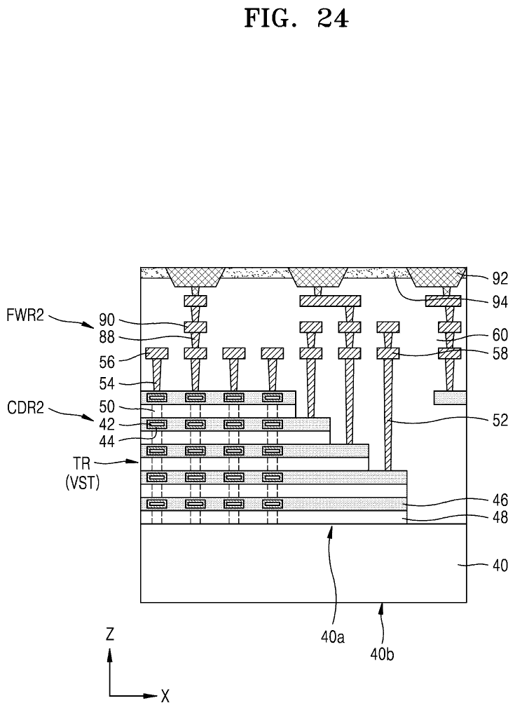

Referring to FIG. 24, the cell array element layer CDR2, the cell wiring level layer FWR2, the cell bonding pad 92, and the cell bonding layer 94 are formed on the cell substrate layer 40. The cell substrate layer 40, the cell array element layer CDR2, the cell bonding pad 92, and the cell bonding layer 94 constitute a memory cell array structure (MCA2 in FIG. 7).

The cell substrate layer 40 may include a silicon substrate or a silicon-germanium substrate. However, example embodiments are not limited thereto. The cell substrate layer 40 may include the upper surface 40a and the lower surface 40b. The cell array element layer CDR2 may include the cell transistor TR and a cell capacitor (CAP of FIGS. 2 and 3). The cell transistor TR may be a three-dimensional vertical stack transistor VST.

The cell array element layer CDR2 may include the channel region 42, the gate insulating layer 44, the word lines 46, the first cell interlayer insulating patterns 48, and the bit lines 50. The cell array element layer CDR2 may include the first cell contact plug 52, the first cell pad 58, the second cell contact plug 54, the second cell pad 56, and the second cell interlayer insulating layer 60.

The cell wiring level layer FWR2 may be formed on the cell array element layer CDR2. The cell wiring level layer FWR2 may include the third cell contact plug 88 connected to the first and second cell pads 58 and 56 and the first cell wiring layer 90 connected to the third cell contact plug 88.

The cell bonding pad 92 and the cell bonding layer 94 are formed on the cell wiring level layer FWR2. The cell bonding pad 92 includes a metal layer, for example, a copper layer. The cell bonding layer 94 includes an insulating layer, such as a silicon oxide layer or a silicon nitride layer.

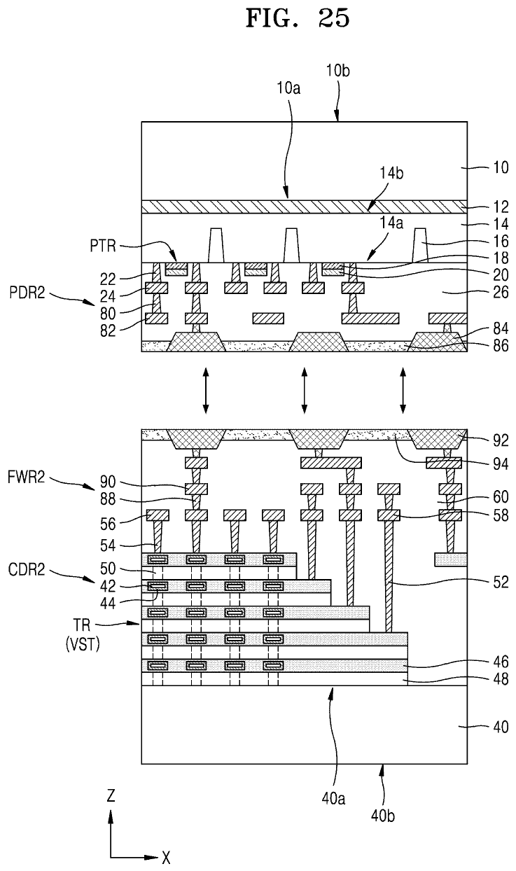

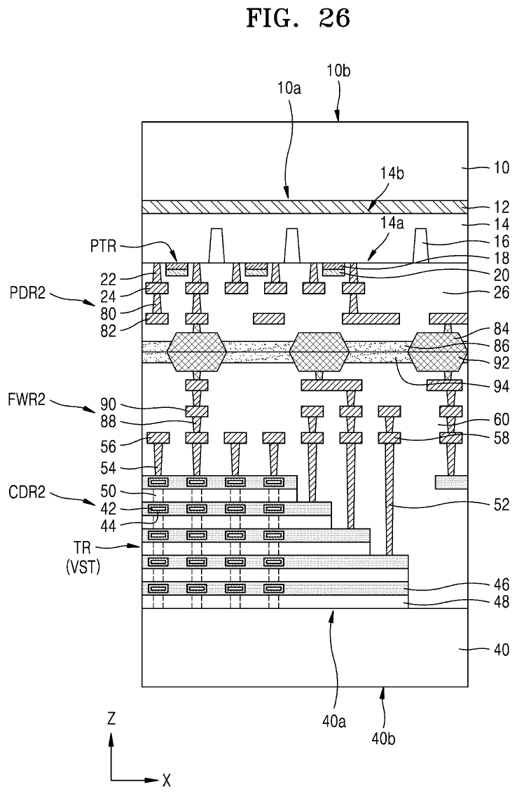

Referring to FIGS. 25 and 26, a resultant product of FIG. 23 is turned over as illustrated in FIG. 25. Then the peripheral circuit element layer PDR2 is located at the bottom. The upper surface 14a of the peripheral epi layer 14 is located at the bottom, and the peripheral bonding pad 84 and the peripheral bonding layer 86 are located at the lowest part.

The cell array element layer CDR2 may be provided on the cell substrate layer 40. The peripheral circuit element layer PDR2 including, in a lower portion thereof, the upper surface 14a of the peripheral epi layer 14 and the peripheral bonding pad 84 and the peripheral bonding layer 86 in a lowest portion thereof is positioned above the cell wiring level layer FWR2, the cell bonding pad 92, and the cell bonding layer 94.

Next, as illustrated in FIG. 26, the peripheral bonding pad 84, the peripheral bonding layer 86, the cell bonding pad 92, and the cell bonding layer 94 are bonded through a heat treatment process (or annealing process). The peripheral bonding pad 84 and the peripheral bonding layer 86 are bonded to the cell bonding pad 92 and the cell bonding layer 94 through a heat treatment process, respectively.

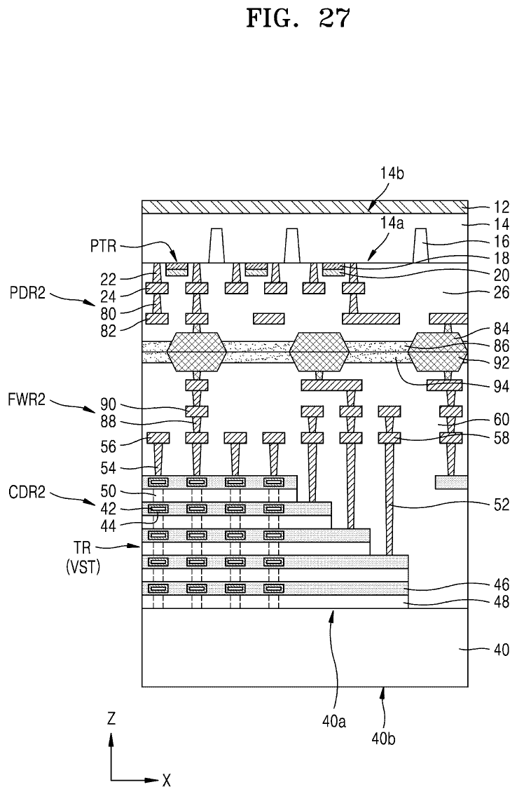

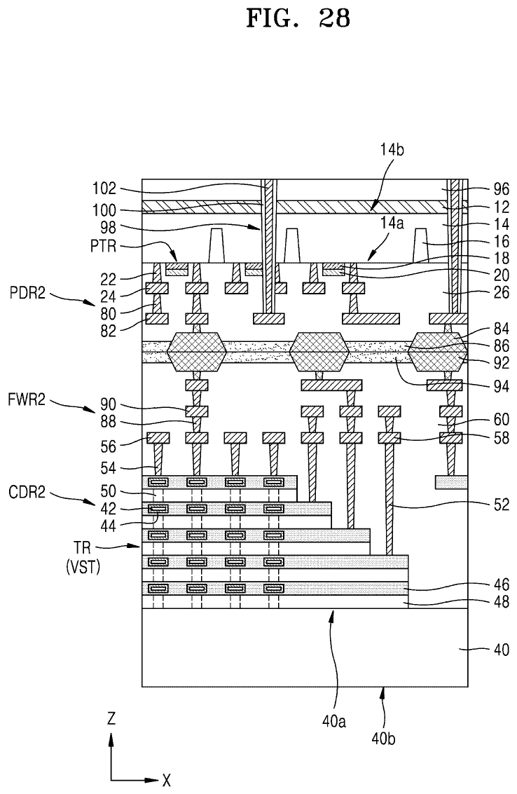

Referring to FIGS. 27 and 28, the first support substrate layer (10 of FIG. 26) is removed through a chemical mechanical polishing process as illustrated in FIG. 27. During the chemical mechanical polishing process, the etch stopping layer 12 may act as an etch stopping point.

During the chemical mechanical polishing process, the etch stopping layer 12 acts as an etch stopping point, thereby suppressing thickness loss of the peripheral epi layer 14. The peripheral epi layer 14 may also improve thickness uniformity by suppressing thickness loss during the manufacturing process by using the etch stopping layer 12.

As illustrated in FIG. 28, after forming the second peripheral interlayer insulating layer 96 disposed on the etch stopping layer 12, a second connection contact plug 102 vertically connected to the peripheral circuit element layer PDR2 is formed. The second connection contact plug 102 may connect the third peripheral wiring layer 104 to the second peripheral wiring layer 82.

The second connection contact plug 102 may be formed in the second connection contact hole 98 formed within the peripheral epi layer 14, the etch stopping layer 12, and the first peripheral interlayer insulating layer 26. The second connection contact plug 102 may be insulated from the peripheral epi layer 14 by the liner insulating layer 100 formed on the inner wall of the second connection contact hole 98.

Further, as illustrated in FIG. 7, the peripheral wiring level layer BWR2 is formed on the second peripheral interlayer insulating layer 96 to complete the semiconductor memory device EM3. The peripheral wiring level layer BWR2 may include the fourth peripheral contact plug 106, the third peripheral wiring layer 104, the third peripheral interlayer insulating layer 108, and the peripheral pad 110.

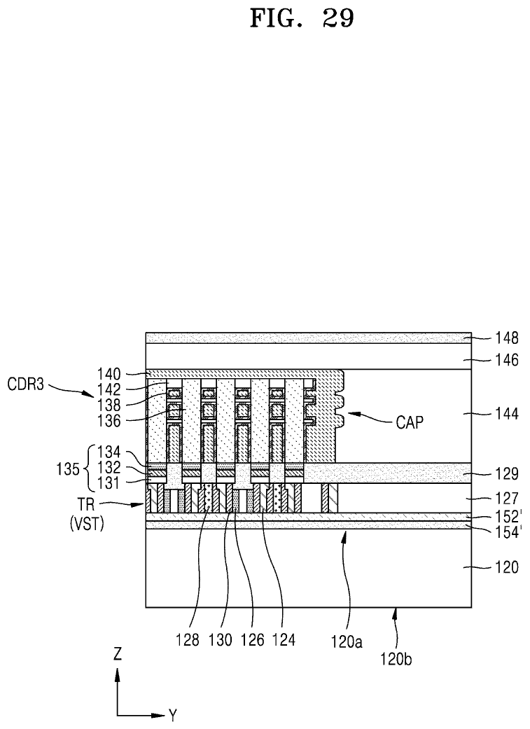

FIGS. 29 to 37 are cross-sectional views to describe a method of manufacturing the semiconductor memory device EM5 of FIGS. 11 to 13.

In FIGS. 29 to 37, the same reference numerals as those of FIGS. 11 to 13 denote the same members. In FIGS. 29 to 37, the details described with reference to FIGS. 11 to 13 are briefly described or omitted.

Referring to FIG. 29, the cell array element layer CDR3 is formed on a third support substrate layer 120. The third support substrate layer 120 may include an upper surface 120a and a lower surface 120b. The third support substrate layer 120 may include a silicon substrate.

The cell array element layer CDR3 may include a capping material layer 154′ for a bit line, a metal layer 152′ for a bit line, the cell transistor TR, the contact layer 135, and the cell capacitor CAP. The capping material layer 154′ for a bit line may include an insulating layer, such as a silicon oxide layer or a silicon nitride layer. However, example embodiments are not limited thereto.

The cell transistor TR may be a vertical channel transistor VCT. The cell transistor TR may include the semiconductor layer 124 including a channel layer and a source/drain, the gate insulating layer 130, and the gate electrodes 126, 128. The gate electrode 128 may be referred to as a back gate electrode. The gate electrodes 126, 128 may be connected to the word line WL in the first horizontal direction X as illustrated in FIG. 10. Each component of the cell transistor TR may be insulated by a transistor insulating layer 127.

The cell capacitor CAP may include a laminated capacitor including the first electrode 136, the capacitor dielectric layer 138, and the second electrode 140. The cell capacitor CAP may be insulated by the capacitor insulating layer 144. The cell capacitor CAP may be connected to the cell transistor TR through the contact layer 135. The contact layer 135 may be insulated by the contact insulating layer 129.

The contact layer 135 may include a plurality of layers, for example, the first to third material layers 131, 132, and 134. The contact layer 135 may include a metal layer. However, example embodiments are not limited thereto. In some example embodiments, the first material layer 131 may include a semiconductor material doped with impurities, such as a silicon layer. However, example embodiments are not limited thereto.

The cell array element layer CDR3 may include the capping insulating layer 146 and the substrate bonding layer 148. The capping insulating layer 146 may include a silicon oxide layer. The capping insulating layer 146 may be formed on the cell capacitor CAP and the capacitor insulating layer 144. The substrate bonding layer 148 may be formed on the capping insulating layer 146. The substrate bonding layer 148 may include a silicon oxide layer or a silicon nitride layer. However, example embodiments are not limited thereto.

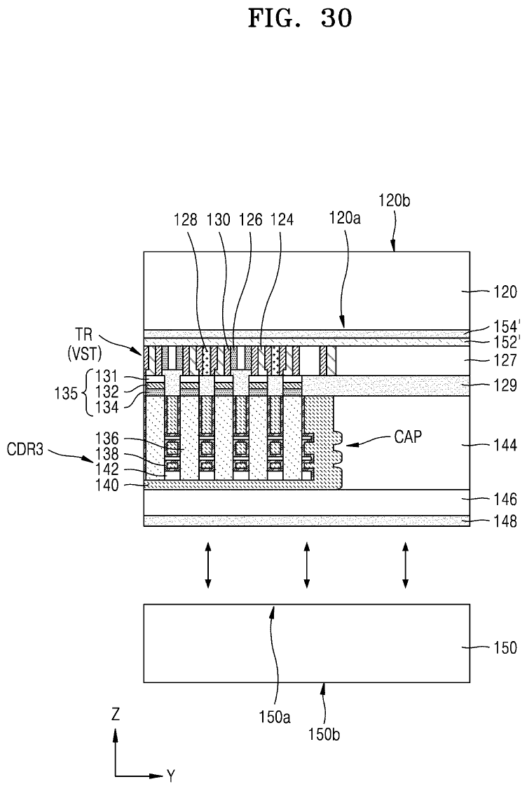

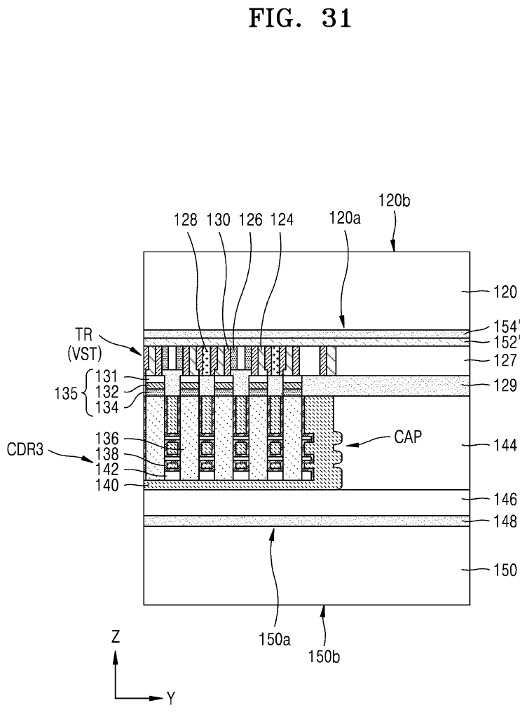

Referring to FIGS. 30 and 31, a resultant product of FIG. 29 is turned over as illustrated in FIG. 30. Then the cell array element layer CDR3 is located at the bottom, and the capping insulating layer 146 and the substrate bonding layer 148 are positioned at the lowermost part. The cell array element layer CDR3 is positioned on the cell substrate layer 150, with the substrate bonding layer 148 located at the lowermost part.

Next, as illustrated in FIG. 31, the capping insulating layer 146 and the substrate bonding layer 148 are bonded to each other through a heat treatment process (or annealing process).

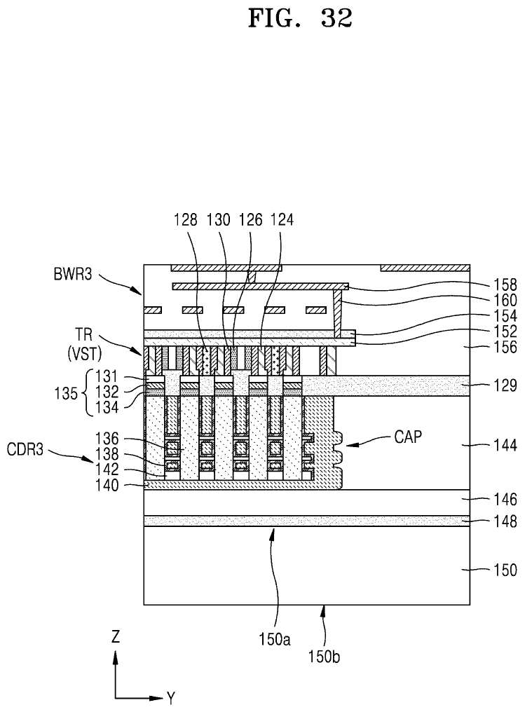

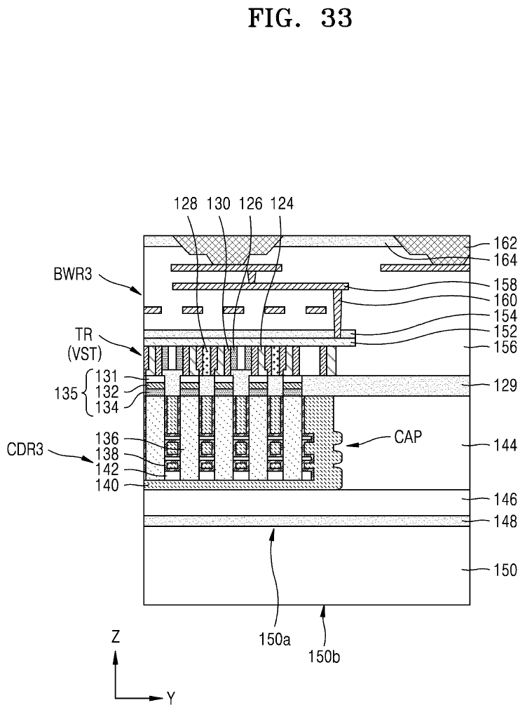

Referring to FIGS. 32 and 33, the third support substrate layer (120 of FIG. 31) is removed by a chemical mechanical polishing process as illustrated in FIG. 32. During the chemical mechanical polishing process, the capping material layer 154′ for a bit line may act as an etch stopping point. The capping material layer 154′ for a bit line and a metal layer 152′ for a bit line are patterned to form the bit line capping layer 154 and the bit line 152.

Next, the cell wiring level layer BWR3 is formed on the cell array element layer CDR3. The cell wiring level layer BWR3 may include a fourth cell contact plug 160 connected to the bit line 152 and a second cell wiring layer 158 connected to the fourth cell contact plug 160. The fourth cell contact plug 160 and the second cell wiring layer 158 may be insulated by the third cell interlayer insulating layer 156.

As illustrated in FIG. 33, the cell bonding pad 162 and the cell bonding layer 164 are formed on the cell wiring level layer BWR3. The cell bonding pad 162 may include a metal layer, such as a copper layer. However, example embodiments are not limited thereto. The cell bonding layer 164 may include an insulating layer, such as a silicon oxide layer or a silicon nitride layer. However, example embodiments are not limited thereto.

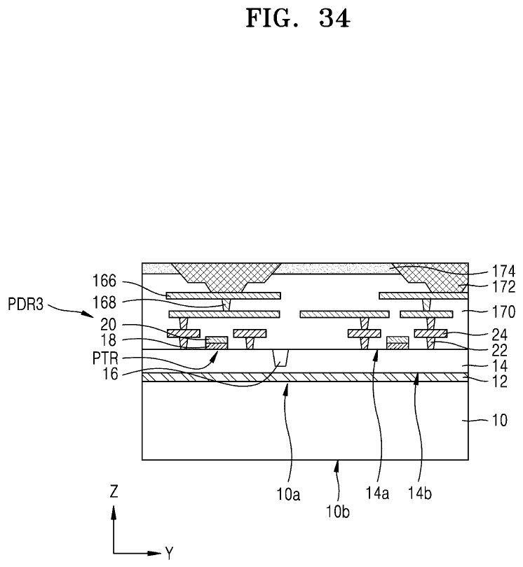

Referring to FIG. 34, the peripheral circuit element layer PDR3 constituting a peripheral circuit structure (PCR3 of FIG. 11) is formed on the first support substrate layer 10. The first support substrate layer 10 may include a silicon substrate. The first support substrate layer 10 may include the upper surface 10a and the lower surface 10b. The peripheral circuit element layer PDR3 may be formed on the upper surface 10a of the first support substrate layer 10.

The peripheral circuit element layer PDR3 may include the etch stopping layer 12, the peripheral epi layer 14, the peripheral transistor PTR, the first peripheral contact plug 22, the first peripheral wiring layer 24, the fourth peripheral interlayer insulating layer 170, the fifth peripheral contact plug 168, and the fourth peripheral wiring layer 166.

The etch stopping layer 12 is formed by depositing a semiconductor epi layer on the first support substrate layer 10. The etch stopping layer 12 may include a SiGe layer, a SiGeC layer, or a SiGeB layer. The peripheral epi layer 14 is formed on the etch stopping layer 12. The peripheral epi layer 14 may include the upper surface 14a and the lower surface 14b. The peripheral epi layer 14 includes a silicon layer or a silicon-germanium layer. However, example embodiments are not limited thereto.

The peripheral transistor PTR is formed on the upper surface 14a of the peripheral epi layer 14. The peripheral transistor PTR may include a peripheral gate insulating layer, a peripheral gate electrode 18, and a peripheral gate capping layer 20 formed on the upper surface 14a of the peripheral epi layer 14. The peripheral circuit element layer PDR3 may include the peripheral epi layer 14 with the upper surface 14a facing an upward direction, and the device isolation layer 16 arranged within the peripheral epi layer 14.

The first peripheral contact plug 22, the first peripheral wiring layer 24, the fifth peripheral contact plug 168, and the fourth peripheral wiring layer 166 connected to the peripheral transistor PTR are formed on the peripheral transistor PTR. The fourth peripheral interlayer insulating layer 170 may insulate between the first peripheral contact plug 22, the first peripheral wiring layer 24, the fifth peripheral contact plug 168, and the fourth peripheral wiring layer 166.

The peripheral circuit structure PCR3 forms the peripheral bonding pad 172 and the peripheral bonding layer 174 on the fourth peripheral interlayer insulating layer 170. The peripheral bonding pad 172 may be connected to the fourth peripheral wiring layer 166. The peripheral bonding pad 172 may include a metal layer, for example, a copper layer. However, example embodiments are not limited thereto. The peripheral bonding layer 174 may include an insulating layer, such as a silicon oxide layer or a silicon nitride layer. However, example embodiments are not limited thereto.

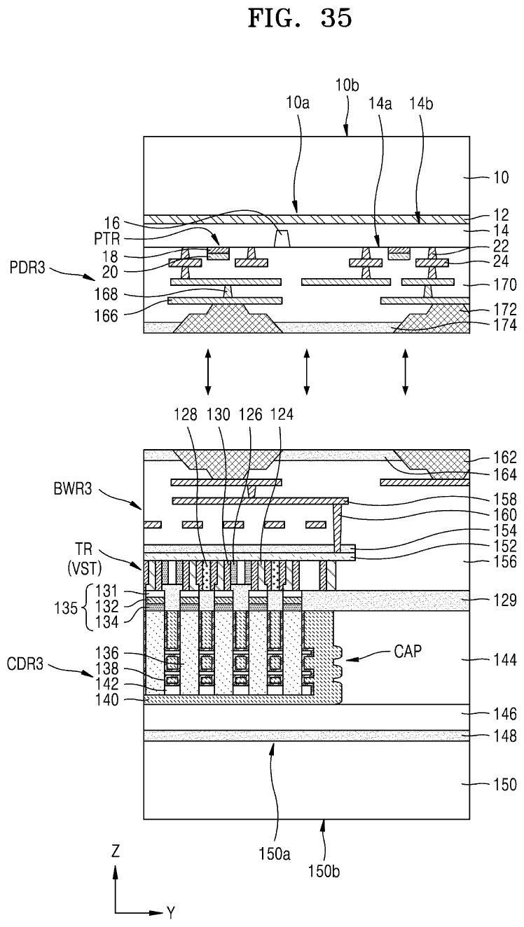

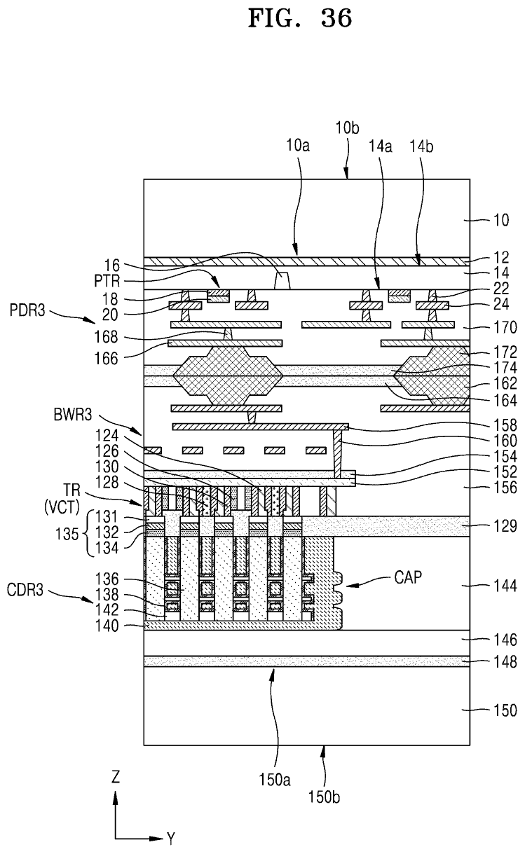

Referring to FIGS. 35 and 36, a resultant product of FIG. 34 is turned over as illustrated in FIG. 35. Then the peripheral circuit element layer PDR3 is located at the bottom. The upper surface 14a of the peripheral epi layer 14 is located at the bottom, and the peripheral bonding pad 172 and the peripheral bonding layer 174 are located at the lowest part.

The cell array element layer CDR3 provided on the cell substrate layer 150. The peripheral circuit element layer PDR3 including, in a lower portion thereof, the upper surface 14a of the peripheral epi layer 14 and the peripheral bonding pad 172 and the peripheral bonding layer 174 in a lowest portion thereof is located above the cell wiring level layer BWR3, the cell bonding pad 162, and the cell bonding layer 164.

Next, as illustrated in FIG. 36, the peripheral bonding pad 172, the peripheral bonding layer 174, the cell bonding pad 162, and the cell bonding layer 164 are bonded to each other through a heat treatment process (or annealing process). The peripheral bonding pad 172 and the peripheral bonding layer 174 are bonded to the cell bonding pad 162 and the cell bonding layer 164 through a heat treatment process, respectively.

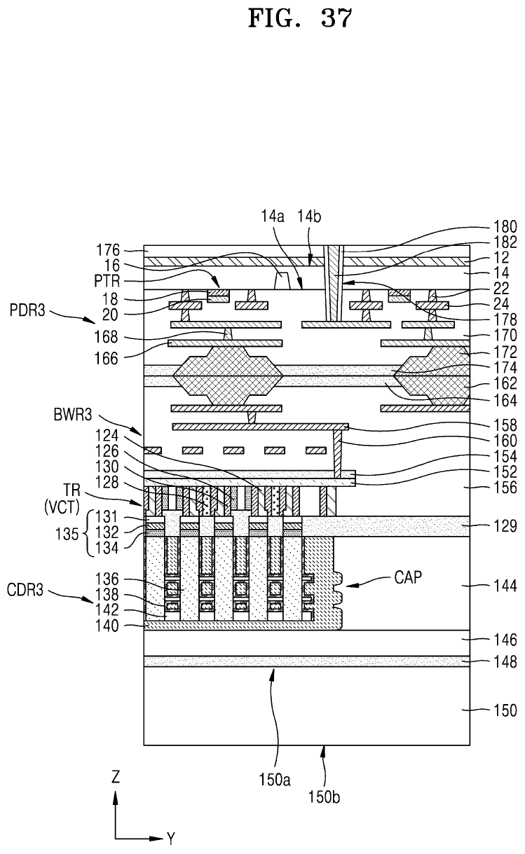

Referring to FIG. 37, the first support substrate layer (10 of FIG. 36) is removed through a chemical mechanical polishing process. During the chemical mechanical polishing process, the etch stopping layer 12 may act as an etch stopping point.

During the chemical mechanical polishing process, the etch stopping layer 12 acts as an etch stopping point, thereby suppressing thickness loss of the peripheral epi layer 14. The peripheral epi layer 14 may also improve thickness uniformity by suppressing, by using the etch stopping layer 12, thickness loss during the manufacturing process.

Further, after forming the fifth peripheral interlayer insulating layer 176 on the etch stopping layer 12, the third connection contact plug 182 that vertically connects the peripheral circuit element layer PDR3 and the peripheral wiring level layer BWR4 is formed. The third connection contact plug 182 may be connected to the fourth peripheral wiring layer 166.

The second connection contact plug 102 may be formed in the second connection contact hole 98 formed within the peripheral epi layer 14, the etch stopping layer 12, and the first peripheral interlayer insulating layer 26. The third connection contact plug 182 may be arranged in the third connection contact hole 178 located within the peripheral epi layer 14, the etch stopping layer 12, and the fifth peripheral interlayer insulating layer 176. The third connection contact plug 182 may be insulated from the peripheral epi layer 14 by the liner insulating layer 180 formed on the inner wall of the third connection contact hole 178.

Further, as illustrated in FIG. 11, the peripheral wiring level layer BWR4 is formed on the fifth peripheral interlayer insulating layer 176 to complete the semiconductor memory device EM5. The peripheral wiring level layer BWR4 may include the sixth peripheral contact plug 184, the fifth peripheral wiring layer 186 connected to the sixth peripheral contact plug 184, and the sixth peripheral interlayer insulating layer 188 that insulates the sixth peripheral contact plug 184 and the fifth peripheral wiring layer 186.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments of the inventive concepts has been particularly shown and described with reference to example embodiments thereof, it will be understood that various changes in form and details may be made therein without departing from the spirit and scope of the following claims.

What is claimed is:

1. A semiconductor memory device comprising:
a memory cell array structure;
the memory cell array structure comprising
a cell substrate layer,
a cell array element layer on the cell substrate layer,
the cell array element layer including a cell transistor and a cell capacitor, and
a cell bonding layer on the cell array element layer;
a peripheral circuit structure stacked on the memory cell array structure; and
the peripheral circuit structure comprising
a peripheral epi layer, the peripheral epi layer having an upper surface facing an upward or downward direction,
a peripheral circuit element layer on the peripheral epi layer, the peripheral circuit element layer including a peripheral transistor,
an etch stopping layer on a lower surface of the peripheral epi layer, and
a peripheral bonding layer bonded to the cell bonding layer.

2. The semiconductor memory device of claim 1, wherein the etch stopping layer comprises a semiconductor epi layer.

3. The semiconductor memory device of claim 2, wherein the etch stopping layer comprises at least one of a SiGe layer, a SiGeC layer, and a SiGeB layer.

4. The semiconductor memory device of claim 1, wherein the peripheral bonding layer is on a lower surface of the etch stopping layer.

5. The semiconductor memory device of claim 1, wherein the cell bonding layer is above the cell substrate layer,
the peripheral bonding layer is below the peripheral epi layer, and
the cell bonding layer and the peripheral bonding layer are bonded to each other.

6. The semiconductor memory device of claim 1, wherein
the memory cell array structure further comprises
a cell bonding pad within the cell bonding layer,
the peripheral circuit structure further comprises a peripheral bonding pad within the peripheral bonding layer,
the cell bonding layer and the cell bonding pad are arranged above the cell substrate layer,
the peripheral bonding layer and the peripheral bonding pad are above the peripheral epi layer, and
the cell bonding layer and the cell bonding pad are bonded to the peripheral bonding layer and the peripheral bonding pad on the peripheral epi layer, respectively.

7. The semiconductor memory device of claim 1, wherein the cell transistor comprises a three-dimensional vertical stacked transistor or a vertical channel transistor.

8. The semiconductor memory device of claim 1, wherein the peripheral circuit structure further comprises a contaminant penetration prevention layer on a lower surface or an upper surface of the etch stopping layer.

9. The semiconductor memory device of claim 8, wherein the contaminant penetration prevention layer comprises a metal layer.

10. A semiconductor memory device comprising:
a memory cell array structure;
the memory cell array structure comprising
a cell substrate layer,
a cell array element layer on the cell substrate layer,
the cell array element layer including a cell transistor and a cell capacitor, and
a cell bonding layer on the cell array element layer;
a peripheral circuit structure stacked on the memory cell array structure;
the peripheral circuit structure comprising
a peripheral epi layer having an upper surface facing an upward direction,
a peripheral circuit element layer on the peripheral epi layer,
the peripheral circuit element layer including a peripheral transistor,
an etch stopping layer on a lower surface of the peripheral epi layer,
a peripheral bonding layer on a lower surface of the etch stopping layer, and
the peripheral bonding layer bonded to the cell bonding layer; and
a connection contact plug vertically connecting the cell array element layer to the peripheral circuit element layer.

11. The semiconductor memory device of claim 10, wherein the etch stopping layer comprises a semiconductor epi layer comprising at least one of a SiGe layer, a SiGeC layer, and a SiGeB layer.

12. The semiconductor memory device of claim 10, wherein the cell array element layer includes a cell pad,
the peripheral circuit element layer includes a peripheral wiring layer and a peripheral pad connected to the peripheral wiring layer, and
the connection contact plug vertically connects the peripheral pad to the cell pad.

13. The semiconductor memory device of claim 10, wherein the cell transistor comprises a three-dimensional vertical stacked transistor.

14. The semiconductor memory device of claim 10, wherein
the peripheral circuit structure further comprises
a contaminant penetration prevention layer between the peripheral bonding layer and the etch stopping layer, and
the contaminant penetration prevention layer comprising a metal layer.

15. A semiconductor memory device comprising:
a memory cell array structure;
the memory cell array structure comprising
a cell substrate,
a cell array element layer on the cell substrate,
the cell array element layer including a cell transistor and a cell capacitor,
a cell bonding layer on the cell array element layer, and
a cell bonding pad within the cell bonding layer;
a peripheral circuit structure stacked on the memory cell array structure; and
the peripheral circuit structure comprising
a peripheral epi layer having an upper surface facing a downward direction,
a peripheral circuit element layer on the upper surface of the peripheral epi layer,
the peripheral circuit element layer including a peripheral transistor,
an etch stopping layer on a lower surface of the peripheral epi layer,
a peripheral bonding layer on an upper surface of the peripheral circuit element layer,
the peripheral bonding layer bonded to the cell bonding layer,
a peripheral bonding pad within the peripheral bonding layer, and
the peripheral bonding pad bonded to the cell bonding pad.

16. The semiconductor memory device of claim 15, wherein the etch stopping layer comprises a semiconductor epi layer comprising at least one of a SiGe layer, a SiGeC layer, and a SiGeB layer.

17. The semiconductor memory device of claim 15, wherein
the memory cell array structure further comprises
a cell wiring level layer on the cell array element layer, and
the cell wiring level layer connected to the cell bonding pad.

18. The semiconductor memory device of claim 15, wherein
the peripheral circuit element layer comprises
an upper surface peripheral wiring layer connected to the peripheral bonding pad, and
the peripheral circuit structure further comprises
a peripheral wiring level layer including a lower surface peripheral wiring layer on the etch stopping layer, and
a connection contact plug vertically connecting the upper surface peripheral wiring layer to the lower surface peripheral wiring layer.

19. The semiconductor memory device of claim 15, wherein the cell transistor comprises a three-dimensional vertical stacked transistor or a vertical channel transistor.

20. The semiconductor memory device of claim 15, wherein
the peripheral circuit structure further comprises
a contaminant penetration prevention layer on the etch stopping layer, and
the contaminant penetration prevention layer comprising a metal layer.
